(19) United States
(12) Patent Application Publication
(10) Pub. No.: US 2025/0133741 A1
(43) Pub. Date: Apr. 24, 2025

(54) THREE-DIMENSIONAL FERROELECTRIC MEMORY DEVICE AND METHODS OF FABRICATING THE SAME

(71) Applicant: Tokyo Electron Limited, Tokyo (JP)

(72) Inventors: Partha MUKHOPADHYAY, Oviedo, FL (US); Henry Jim FULFORD, Albany, NY (US); Mark I. GARDNER, Albany, NY (US)

(73) Assignee: Tokyo Electron Limited, Tokyo (JP)

(21) Appl. No.: 18/597,801

(22) Filed: Mar. 6, 2024

Related U.S. Application Data
(60) Provisional application No. 63/545,128, filed on Oct. 20, 2023.

(51) Int. Cl. H10B 51/20; H10B 51/30

(52) U.S. Cl. CPC H10B 51/20; H10B 51/30

(57) ABSTRACT

A semiconductor device includes a first gate structure, a second gate structure, and a semiconductor layer. The first gate structure, the semiconductor layer, and the second gate structure are arranged concentrically. The first gate structure includes a first gate electrode and a ferroelectric layer. The second gate structure includes a second gate electrode and a gate dielectric layer. The semiconductor layer is disposed between the ferroelectric layer and the gate dielectric layer.

### CROSS-REFERENCE TO RELATED APPLICATIONS

This application claims priority to U.S. Provisional Application No. 63/545,128, filed Oct. 20, 2023, which is incorporated by reference in its entirety.

### FIELD OF THE DISCLOSURE

This disclosure relates to microelectronic devices including semiconductor devices, transistors, and integrated circuits, including methods of microfabrication. Particularly, the semiconductor devices can include a three-dimensional (3D) ferroelectric memory device.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate, such as memory devices. Historically, with microfabrication, transistors have been created in one plane, with wiring or metallization formed above the active device plane and have thus been characterized as two-dimensional (2D) circuits or 2D fabrication. Moreover, memory devices formed according to such fabrication typically stored a single bit per transistor. Scaling efforts have greatly increased the number of transistors per unit area in 2D circuits, yet scaling efforts are running into greater challenges as scaling enters single digit nanometer semiconductor device fabrication nodes, and additional memory capacity or density is used. Semiconductor device fabricators have expressed a desire for 3D semiconductor circuits for high density, high performance memory applications.

### SUMMARY

A multi-bit memory cell includes a semiconductor channel of a gate-all-around (GAA) transistor, such as a GAA filed-effect transistor (FET). The channel is gated by pair of gate structures which may be disposed, for example, along an inner and outer sidewall of the channel, such that the current flows vertically along the channel according to a voltage of the gate structures. One gate structure can include a gate high-k metal gate stack (HKMG), comprising a high-k dielectric and another dielectric, such as an interfacial dielectric. Another gate structure can include a ferroelectric material configured to polarize upon an application of a control voltage.

The techniques described herein include methods and devices for 3D fabrication of semiconductor devices. Techniques herein can be used for any geometry device (e.g., circular, rectangular, or elliptical). For example, in some embodiments, the transistor may be substantially circular along a lateral plane, with the channel concentrically circumscribed by one gate structure and concentrically circumscribing another gate structure.

One aspect of the present disclosure is directed to a semiconductor device. The semiconductor device includes a first gate structure, a second gate structure, and a semiconductor layer. The first gate structure, the semiconductor layer, and the second gate structure are arranged concentrically. The first gate structure includes a first gate electrode and a ferroelectric layer. The second gate structure includes a second gate electrode and a gate dielectric layer. The semiconductor layer is disposed between the ferroelectric layer and the gate dielectric layer.

The semiconductor layer may surround an outer sidewall of the first gate structure. In some embodiments, semiconductor layer surrounds an outer sidewall of the first gate structure. In some embodiments, the semiconductor layer surrounds an outer sidewall of the second gate structure. In some embodiments, the semiconductor layer comprises a conductive oxide material. In some embodiments, a bottom portion of the semiconductor layer extends along a bottom portion of the gate dielectric layer.

The semiconductor device may further include a first intermediate dielectric layer extending between the ferroelectric layer and the semiconductor layer, and a second intermediate dielectric layer extending between the semiconductor layer and the gate dielectric layer. In some embodiments, the semiconductor device further includes a first source/drain contact electrically coupled (or connected) to a bottom portion of the semiconductor layer, and a second source/drain contact electrically coupled to a top portion of the semiconductor layer. In some embodiments, an entirety of the first source/drain contact is adjacent to a sidewall of the ferroelectric layer. In some embodiments, a portion of the first source/drain contact is below the ferroelectric layer.

Another aspect of the present disclosure is directed to a semiconductor device. The semiconductor device includes an inner gate structure, an outer gate structure, and a semiconductor layer. The inner gate structure, the semiconductor layer, and the outer gate structure are arranged concentrically. The inner gate structure includes an inner gate electrode disposed over a ferroelectric layer. The outer gate structure includes an outer gate electrode disposed over a gate dielectric layer. The semiconductor layer wraps around the inner gate structure and includes a conductive oxide.

The inner gate electrode may be embedded in the ferroelectric layer. In some embodiments, the semiconductor device further includes a first source/drain contact electrically coupled to a bottom portion of the semiconductor layer, and a second source/drain contact electrically coupled to a top portion of the semiconductor layer. In some embodiments, the first source/drain contact is laterally adjacent to a bottom portion of the ferroelectric layer. In some embodiments, the first source/drain contact extends along the bottom portion of the semiconductor layer. In some embodiments, the first source/drain contact directly contacts a portion of the inner gate structure. In some embodiments, the first source/drain contact is physically separated from a portion of the inner gate structure.

Yet another aspect of the present disclosure is directed to a method. The method includes forming a first gate structure over a substrate, the first gate structure including a first gate electrode and a ferroelectric layer. The method includes forming a second gate structure including a second gate electrode and a gate dielectric layer. The method includes forming a semiconductor layer sandwiched between the ferroelectric layer and the gate dielectric layer, where the first gate structure, the semiconductor layer, and the second gate structure are formed concentrically.

The step of forming the first gate structure may include forming an opening over the substrate, depositing the ferroelectric layer in the opening, and depositing the first gate electrode over the ferroelectric layer to fill the opening. In some embodiments, the step of forming the semiconductor layer includes depositing the gate dielectric layer over the semiconductor layer. In some embodiments, the step of forming the second gate structure includes depositing the gate dielectric layer over the semiconductor layer and forming the second gate electrode over the gate dielectric layer. In some embodiments, the method further includes forming a bottom contact feature adjacent to the opening before depositing the ferroelectric layer, where the semiconductor layer is formed to directly contact the bottom contact feature.

The step of forming the first gate structure may include forming an opening over the substrate, forming the first gate electrode within the opening, and depositing the ferroelectric layer over the first gate electrode in the opening. In some embodiments, the step of forming the semiconductor layer includes depositing the semiconductor layer over the ferroelectric layer in the opening. In some embodiments, the step of forming the second gate structure includes depositing the gate dielectric layer over the semiconductor layer and forming the second gate electrode over the gate dielectric layer to fill the opening. In some embodiments, the method further includes forming a bottom contact feature over and separated from the substrate before forming the opening, and etching the first gate electrode and the ferroelectric layer to expose the bottom contact feature in the opening, such that the semiconductor layer is formed to directly contact the bottom contact feature.

These and other aspects and implementations are discussed in detail below. The foregoing information and the following detailed description include illustrative examples of various aspects and implementations and provide an overview or framework for understanding the nature and character of the claimed aspects and implementations. The drawings provide illustrations and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise. References to “or” may be construed as inclusive so that any terms described using “or” may indicate any of a single, more than one, and all of the described terms.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flowchart of a method for making a semiconductor device, in accordance with some embodiments.

FIGS. 2A and 2B collectively illustrate a flowchart of a method for making a semiconductor device, in accordance with some embodiments.

FIGS. 3A, 4A, 5A, 6A, 7A, 8A, 9A, 10A, 11A, and 12A each illustrate a planar top view of a semiconductor device during various fabrication stages of the method of FIG. 1, in accordance with some embodiments.

FIGS. 3B, 4B, 5B, 6B, 7B, 8B, 9B, 10B, 11B, and 12B each illustrate a cross-sectional view of the semiconductor device along line AA′ of FIGS. 3A, 4A, 5A, 6A, 7A, 8A, 9A, 10A, 11A, and 12A, respectively, during various fabrication stages of the method of FIG. 1, in accordance with some embodiments.

FIG. 13 illustrates a 3D perspective view of a portion of the semiconductor device as shown in FIGS. 12A and 12B, in accordance with some embodiments.

FIG. 14 illustrates a 3D side view of a portion of the semiconductor device as shown in FIGS. 12A and 12B, in accordance with some embodiments.

FIG. 15 illustrates a cross-sectional view of the semiconductor device along line AA′ of FIGS. 13 and 14, in accordance with some embodiments.

FIGS. 16A, 17A, 18A, 19A, 20A, 21A, 22A, 23A, and 24A each illustrate a planar top view of a semiconductor device during various fabrication stages of the method of FIGS. 2A and 2B, in accordance with some embodiments.

FIGS. 16B, 17B, 18B, 19B, 20B, 21B, 22B, 23B, and 24B each illustrate a cross-sectional view of the semiconductor device along line AA′ of FIGS. 16A, 17A, 18A, 19A, 20A, 21A, 22A, 23A, and 24A, respectively, during various fabrication stages of the method of FIGS. 2A and 2B, in accordance with some embodiments.

FIG. 25 illustrates a 3D perspective view of a portion of the semiconductor device as shown in FIGS. 24A and 24B, in accordance with some embodiments.

FIG. 26 illustrates a cross-sectional view of the semiconductor device along line AA′ of FIG. 25, in accordance with some embodiments.

FIG. 27 illustrates a flowchart of a method for making a semiconductor device, in accordance with some embodiments.

### DETAILED DESCRIPTION

In the following description, reference will be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Reference will be made to the figures, which for the convenience of visualizing the 3D fabrication techniques described herein, illustrate a substrate undergoing a process flow. Unless expressly indicated otherwise, each figure represents one (or a set) of fabrication steps in a process flow for manufacturing the devices described herein. In the figures, connections between conductive layers or materials may be shown. However, it should be understood that these connections between various layers and masks are merely illustrative and are intended to show a capability for providing such connections and should not be considered limiting to the scope of the claims.

Likewise, although the figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a rectangular configuration, other shapes are also contemplated, and indeed the techniques described herein may be implemented in any shape or geometry.

Techniques described herein include systems and methods for 3D fabrication of semiconductor devices. Specifically, techniques include a vertical gate all around (GAA) ferroelectric conductive oxide junction FET (FeFET) which may operate as an n-bit memory cell. For example, according to the present disclosure, high-speed multibit memory is provided. The memory cells can be arrayed, laterally, or vertically (e.g., stacked). Moreover, a height of either of the FeFET or a capacitor can vary according to a desired refresh rate, channel modulation, etc.

Some advantages with techniques herein include a storage of n-bits of information from a combination of a first gate via ferroelectric material polarization, with another channel such as a HKMG. The ferroelectric polarization can operate as a non-volatile storage (e.g., for years, according to some embodiments).

One embodiment described herein includes a dual gate device configured to store four bits. Particularly, the bits may be resolved, by a memory controller according to a current passing through the channel. The current passing through the channel can be modulated by the first and second gates. Other embodiments include additional or fewer bits of operation. For example, other embodiments, can employ additional gates such as a varied drive strength to the two gates depicted herein, or by the employment of additional gates (e.g., along radial or vertical portions of the FeFET).

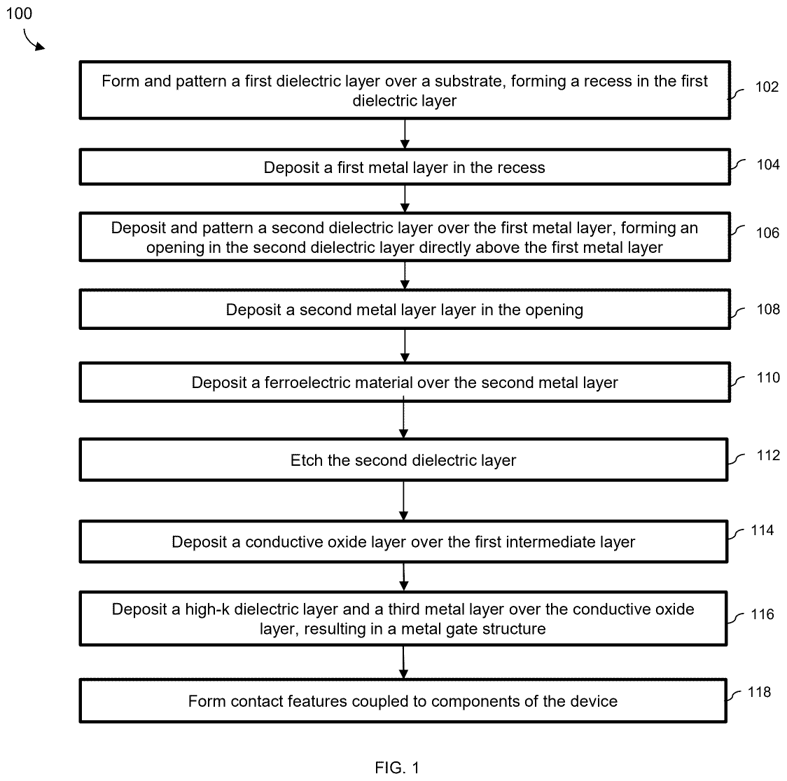

FIG. 1 illustrates a flowchart of an example method 100 for forming an embodiment of a semiconductor device 200. The semiconductor device 200 can include a memory block element, such as memory block elements for a non-volatile memory device. Various memory block elements can be interconnected to form arrays. For example, various instances of the memory cells formed according to the method 100 may be laterally spaced from each other (e.g., according to a row or column). Further, various instances of the memory block elements formed according to the method 100 may be stacked over each other, such as in a repeating pattern. The various interconnections can be connected to form logical rows, columns, pages, blocks, and so forth.

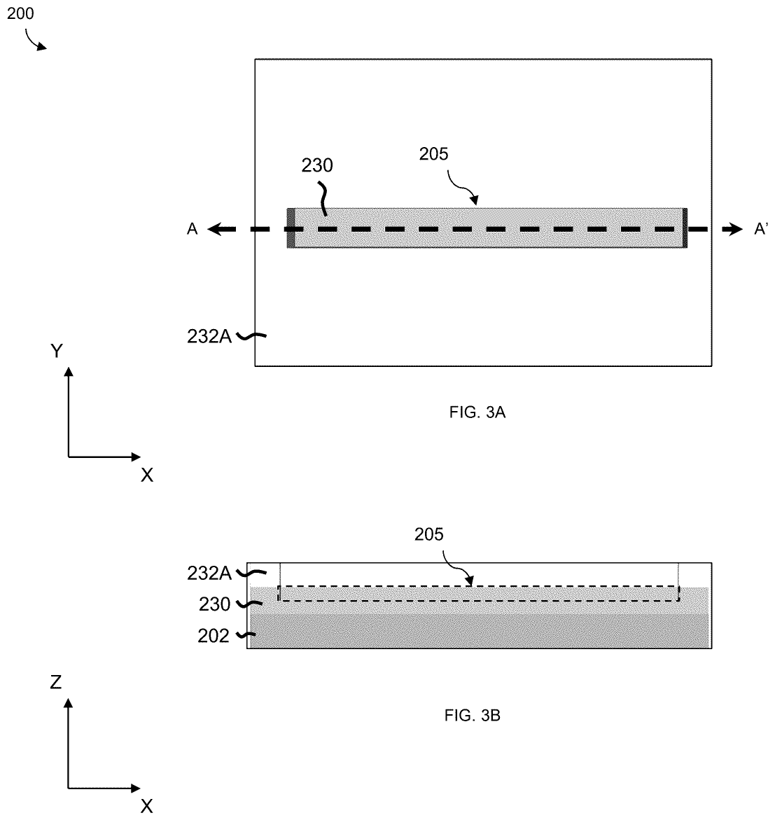

In various embodiments, operations of the method 100 may be associated with top, cross-sectional, or other views of an example semiconductor device at various fabrication stages as shown in FIGS. 3A-15, which will be discussed in further detail below. It should be understood that the semiconductor device 200, shown in FIGS. 3A-15, may include a number of other devices such as inductors, fuses, capacitors, coils, etc., while remaining within the scope of the present disclosure. For example, a semiconductor device can include further layers of stacked transistors or channel portions thereof and interconnections therebetween.

Referring to FIGS. 1, 3A, and 3B, a first dielectric layer 230 is formed over a semiconductor substrate 202 and subsequently patterned to form a recess 205 at operation 102.

The semiconductor substrate 202 includes a semiconductor material substrate, for example, silicon. Alternatively, the semiconductor substrate 202 may include other elementary semiconductor material such as, for example, germanium. The semiconductor substrate 202 may also include a compound semiconductor such as silicon carbide, gallium arsenic, indium arsenide, and indium phosphide. The semiconductor substrate 202 may include an alloy semiconductor such as silicon germanium, silicon germanium carbide, gallium arsenic phosphide, and gallium indium phosphide. In one embodiment, the semiconductor substrate 202 includes an epitaxial layer. For example, the semiconductor substrate 202 may have an epitaxial layer overlying a bulk semiconductor. Furthermore, the semiconductor substrate 202 may include a semiconductor-on-insulator (SOI) structure. For example, the semiconductor substrate 202 may include a buried oxide (BOX) layer formed by a process such as separation by implanted oxygen (SIMOX) or other suitable technique, such as wafer bonding and grinding.

The first dielectric layer 230 includes an oxide, a nitride, a low-k dielectric material (e.g., having a dielectric constant of less than that of silicon oxide, which is about 3.9), the like, or combinations thereof. For example, the first dielectric layer 230 may include silicon oxide, phosphosilicate glass (PSG), borosilicate glass (BSG), boron-doped phosphosilicate glass (BPSG), undoped silicate glass (USG), the like, or combinations thereof. The first dielectric layer 230 may be formed by a process such as chemical oxidation, thermal oxidation, chemical vapor deposition (CVD), high density plasma CVD (HDP-CVD), flowable CVD (FCVD) (e.g., including a CVD-based deposition process implemented in a remote plasma system and a curing process to convert the deposited material to another material, such as an oxide), spin coating, the like, or combinations thereof. Other dielectric materials and/or other formation processes may be used. In an example, the first dielectric layer 230 includes silicon oxide and is formed by a FCVD process. An anneal process may be performed once the first dielectric layer 230 is deposited.

The recess 205 defines a position of a contact feature configured to electrically couple (or connect) to a subsequently formed source/drain from a bottom surface thereof. In some embodiments, the recess 205 is formed by patterning the first dielectric layer 230 using, for example, a series of photolithography and etching techniques. As depicted, the photolithography techniques utilize a photoresist layer that is deposited, irradiated (or exposed), and developed to form a patterned photoresist layer 232A that exposes a portion of the first dielectric layer 230 to be removed (for forming the recess 205). The patterned photoresist layer 232A protects portions of the first dielectric layer 230 from subsequent processing steps, such as etching. Thereafter, the patterned photoresist layer 232A is used to etch the first dielectric layer 230 to form the recess 205 therein. In the present embodiments, the recess 205 does not fully extend through the first dielectric layer 230. Etching the first dielectric layer 230 may be implemented by any suitable process, such as a dry etching process, a wet etching process, a reactive ion etching (RIE) process, the like, or combinations thereof. After etching the first dielectric layer 230, the patterned photoresist layer 232A is removed from the semiconductor device 200 by a suitable process, such as resist stripping or plasma ashing.

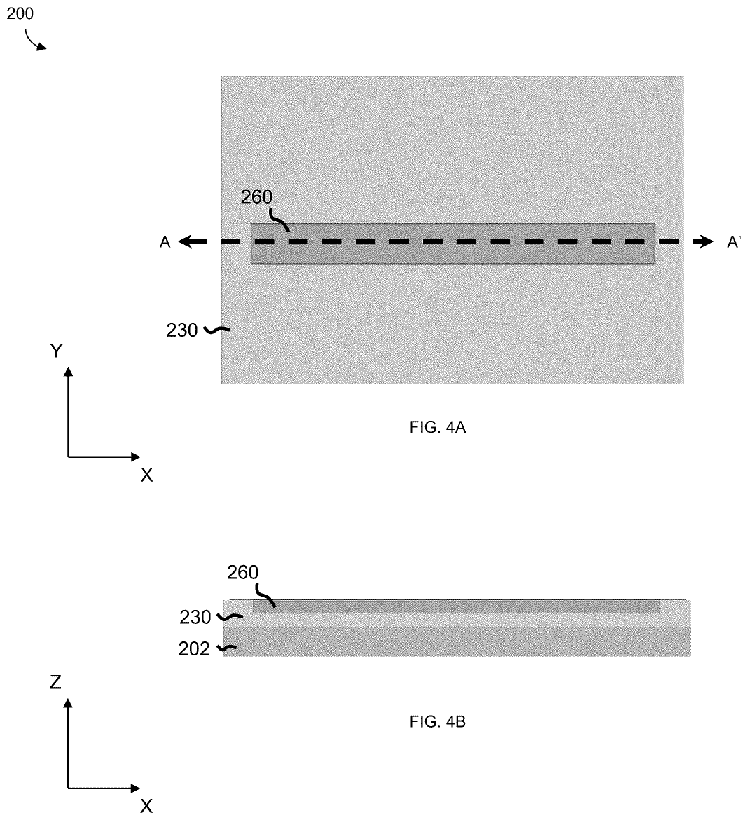

Referring to FIGS. 1, 4A, and 4B, a first metal layer 260 is formed to fill the recess 205 at operation 104. As the first metal layer 260 is configured to electrically couple to a source/drain of the semiconductor device 200, it is alternatively referred to as a bottom contact feature 260 and configured as a portion of a first source/drain contact of the semiconductor device 200.

The first metal layer 260 includes any suitable conductive material (e.g., a metal), such as tungsten, copper, aluminum, ruthenium, cobalt, silver, gold, the like, or combinations thereof. The first metal layer 260 may be deposited using any suitable process, such as CVD, PVD, ALD, electroplating, electroless plating, the like, or combinations thereof. In some embodiments, portions of the first metal layer 260 formed over a top surface of the first dielectric layer 230 are subsequently removed by a chemical-mechanical polishing/planarization (CMP) process, thereby exposing the top surface of the first dielectric layer 230.

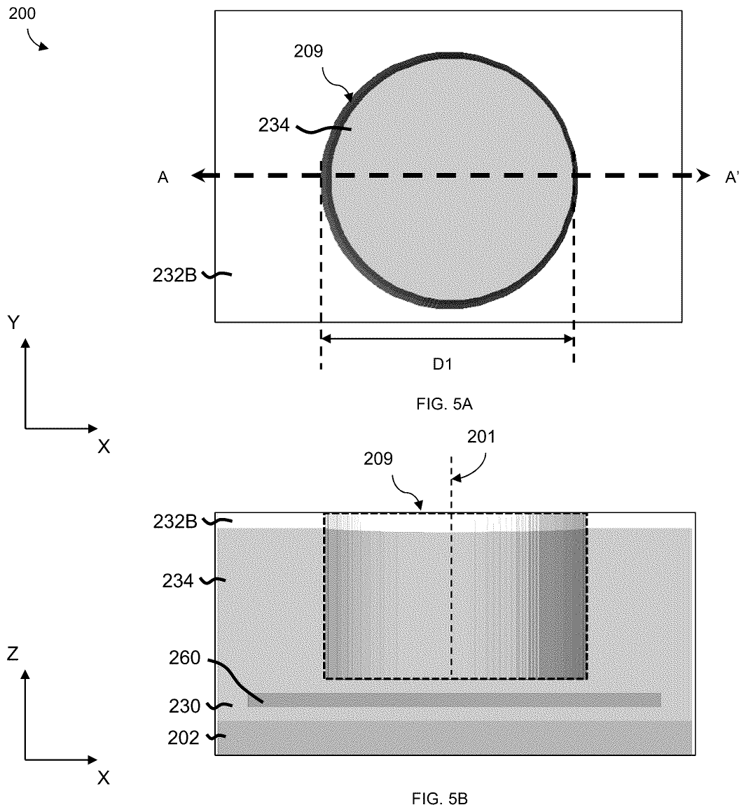

Referring to FIGS. 1, 5A, and 5B, a second dielectric layer 234 is deposited over the first metal layer 260 and subsequently patterned to form an opening 209 at operation 106.

The second dielectric layer 234 includes an oxide, a nitride, a low-k dielectric material, the like, or combinations thereof. For example, the second dielectric layer 234 may include silicon oxide, PSG, BSG, BPSG, USG, the like, or combinations thereof. In some embodiments, the second dielectric layer 234 has the same composition as the first dielectric layer 230 and is formed by a process similar to that described above with respect to forming the first dielectric layer 230.

The opening 209 may be formed in the second dielectric layer 234 by any suitable process. In some embodiments, the opening 209 is formed by a series of photolithography and etching processes similar to those described above with respect to patterning the first dielectric layer 230. For example, as depicted, a patterned photoresist layer 232B is formed over the second dielectric layer 234 to expose a portion of the second dielectric layer 234 corresponding to a position of the opening 209. The patterned photoresist layer 232B is then used as an etch mask to etch the second dielectric layer 234 using a suitable etching process described above, resulting in the opening 209. In the present embodiments, a duration of the etching process is controlled to ensure that the opening 209 does not extend through the second dielectric layer 234 to expose the underlying first metal layer 260. After etching the second dielectric layer 232, the patterned photoresist layer 232B is removed from the semiconductor device 200 by a suitable process, such as resist stripping or plasma ashing.

In the depicted embodiments, the opening 209 has a circular shape in a top view (FIG. 5A) with a diameter D1 in lateral directions (e.g., along X and Y axes) and centered about a central axis 201 extending in a vertical direction (e.g., along Z axis). However, the present disclosure does not limit the opening 209 to any particular configuration. In some examples, the opening 209 may have other configurations, such as an elliptical shape, a rectangular shape, or the like, in the top view.

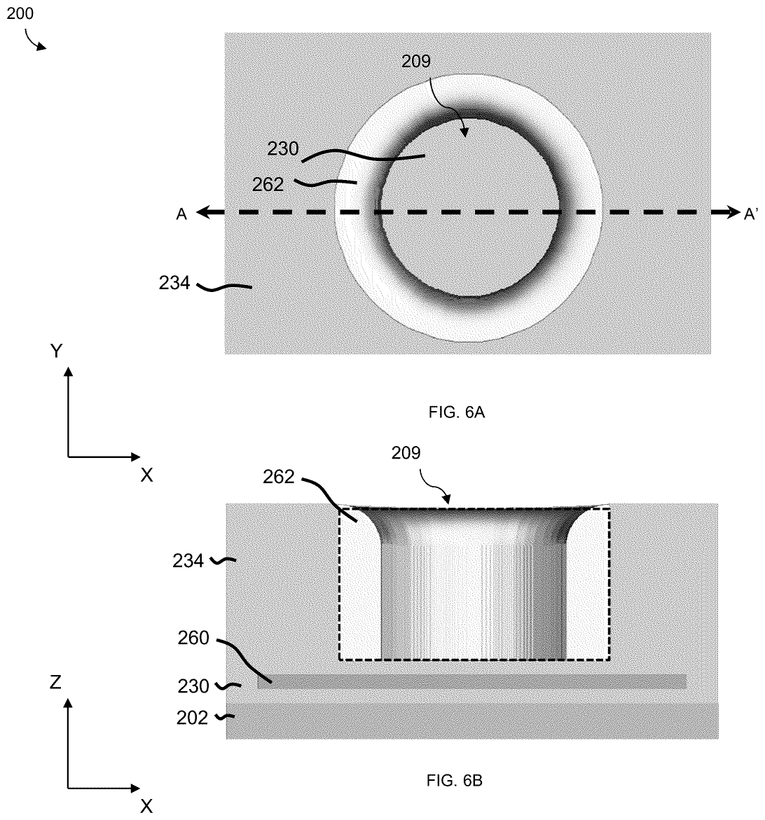

Referring to FIGS. 1, 6A, and 6B, a second metal layer 262 is deposited and subsequently etched in the opening 209 at operation 108. The second metal layer 262 is configured as a gate electrode of a first gate structure G1, which further includes a subsequently formed ferroelectric layer 280. Thus, the second metal layer 262 may be alternatively referred to as the first gate electrode 262.

The second metal layer 262 includes any suitable conductive material (e.g., a metal), such as tungsten, copper, aluminum, ruthenium, cobalt, silver, gold, the like, or combinations thereof. In some embodiments, the second metal layer 262 has the same composition as the first metal layer 260. In the present embodiments, the second metal layer 262 is conformally deposited in the opening 209 and over the top surface of the second dielectric layer 234 using any suitable process, such as ALD, CVD, PVD, the like, or combinations thereof.

Subsequently, portions of the second metal layer 262 are etched by a directional (or anisotropic) etching process to remove a bottom portion of the second metal layer 262, such that remaining portions of the second metal layer 262 only extend along an inner sidewall of the opening 209 as depicted in FIG. 6B. The directional etching process may be implemented using a dry etching process, an RIE process, the like, or combinations thereof. In the present embodiments, the directional etching process is selective to the second metal layer 262 and does not remove, or substantially, remove portions of the second dielectric layer 234.

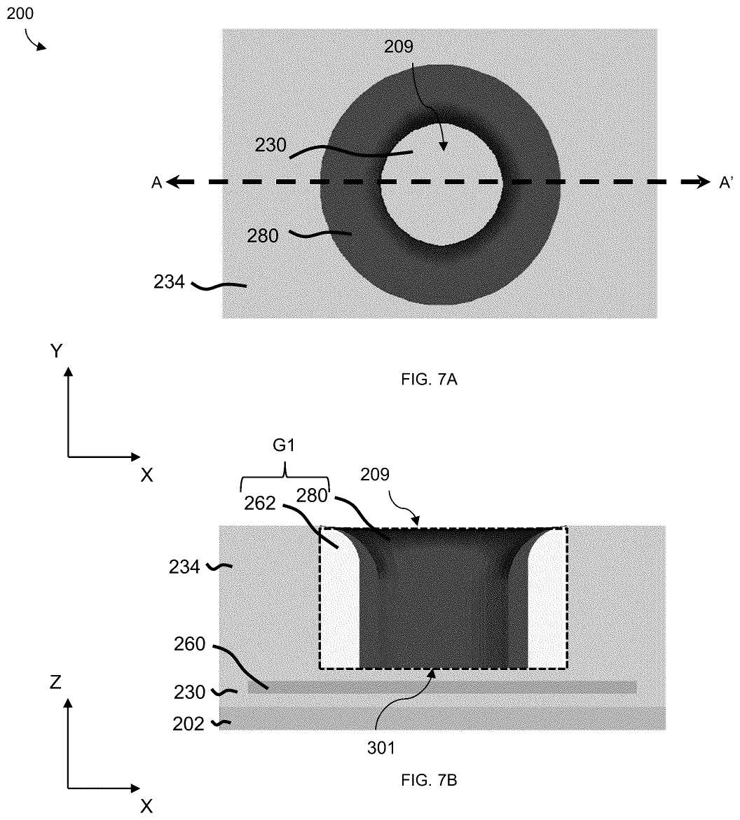

Referring to FIGS. 1, 7A, and 7B, a ferroelectric layer 280 is deposited over the second metal layer 262 and subsequently etched in the opening 209 at operation 110, resulting in the first gate structure G1 in the opening 209. As depicted, a bottom portion 301 of the first gate structure G1 is above and physically separated from the first metal layer 260.

The ferroelectric layer 280 includes a suitable ferroelectric material, such as hafnium oxide (e.g., hafnium oxide containing at least one dopant selected from Al, Zr, and Si and having a ferroelectric non-centrosymmetric orthorhombic phase), zirconium oxide, hafnium-zirconium oxide, bismuth ferrite, barium titanate (e.g., BaTiO₃ (BT)), colemanite (e.g., Ca₂BO₁₁.5H₂O), bismuth titanate (e.g., Bi₄Ti₃O₁₂), europium barium titanate, ferroelectric polymer, germanium telluride, langbeinite (e.g., M₂M′₂(SO₄)₃ in which M is a monovalent metal and M′ is a divalent metal), lead scandium tantalate (e.g., Pb(ScₓTa₁₋ₓ)O₃), lead titanate (e.g., PbTiO₃ (PT)), lead zirconate titanate (e.g., Pb(Zr,Ti)O₃ (PZT)), lithium niobate (e.g., LiNbO₃ (LN)), lanthanum aluminate (LaAlO₃), polyvinylidene fluoride ((CH₂CF₂)n), potassium niobate (e.g., KNbO₃), potassium sodium tartrate (e.g., KNaC₄H₄O₆.4H₂O), potassium titanyl phosphate (e.g., KO₅PTi), sodium bismuth titanate (such as Na_{0.5}Bi_{0.5}TiO₃ or Bi_{0.5}Na_{0.5}TiO₃), lithium tantalate (such as LiTaO₃ (LT)), lead lanthanum titanate (e.g., (Pb,La)TiO₃(PLT)), lead lanthanum zirconate titanate (e.g., (Pb,La)(Zr,Ti)O₃ (PLZT)), ammonium dihydrogen phosphate (such as NH₄H₂PO₄(ADP)), potassium dihydrogen phosphate (e.g., KH₂PO₄ (KDP)), the like, or combinations thereof.

In the present embodiments, the ferroelectric layer 280 is conformally deposited in the opening 209 and over the top surface of the second dielectric layer 234 using any suitable process, such as ALD, CVD, PVD, the like, or combinations thereof. In this regard, sidewall portions of the ferroelectric layer 280 are formed over the second metal layer 262 and a bottom portion of the ferroelectric layer 280 is formed across the bottom surface of the opening 209.

Subsequently, portions of the ferroelectric layer 280 are removed by a directional (or anisotropic) etching process similar to the directional etching process described above with respect to etching the second metal layer 262. In this regard, remaining portions of the ferroelectric layer 280 only extend along the second metal layer 262 as depicted in FIG. 7B. In the present embodiments, the directional etching process is selective to the ferroelectric layer 280 and does not remove, or substantially, remove portions of the second dielectric layer 234.

The ferroelectric layer 280 is subsequently annealed or otherwise processed to exhibit a desired ferroelectric property by changing the crystalline phase of the material in the ferroelectric layer 280. For example, the ferroelectric property can be adjusted according to a desired conductivity modulation of a channel proximal to the ferroelectric layer 280. The annealing or other processing of the ferroelectric material can be performed during the operation 110 or a subsequent operation of the method 100. In some embodiments, performing such an annealing process before forming additional components of the semiconductor device 200 maintains a desired thermal budget without interfering with subsequent operations of the method 100.

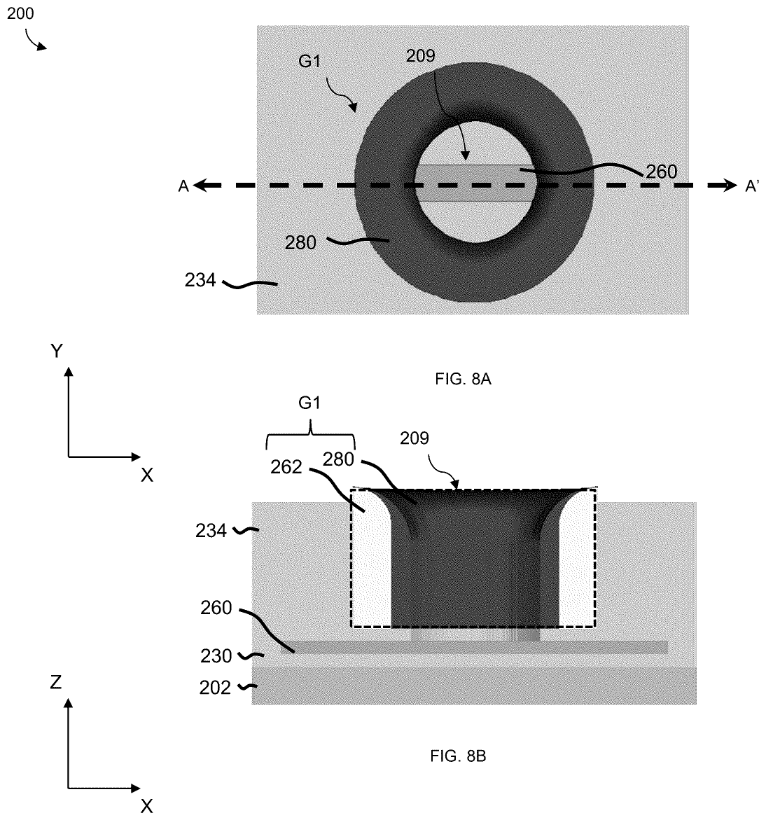

Referring to FIGS. 1, 8A, and 8B, a portion of the second dielectric layer 234 in the opening 209 is etched (or removed) to expose the underlying first metal layer 260 at operation 112.

As depicted in FIG. 7B, for example, the opening 209 exposes the portion of the second dielectric layer 234 configured to insulate portions of the first metal layer 260 from the first gate structure G1. However, in order to provide electrical connection between the first metal layer 260 and a subsequently formed semiconductor layer (e.g., a semiconductor layer 284), the portion of the second dielectric layer 234 in the opening 209 is removed (or punched through) by a directional (or anisotropic) etching process similar to the directional etching process described above with respect to etching the second metal layer 262. Alternatively, the portion of the second dielectric layer 234 in the opening 209 may be removed by a wet (or an isotropic) etching process. As a result, the first metal layer 260 is exposed in the opening 209 after etching the second dielectric layer 234.

In addition, top portions of the second dielectric layer 234 adjacent to the first gate structure G1 are removed by the directional etching process or the wet etching process. Accordingly, the top surface of the semiconductor device 200 as depicted in FIG. 8B may include an exposed surface including portions of the ferroelectric layer 280, the second metal layer 262, or both, according to one or more etchants or operations used to etch the opening 209, the second metal layer 262, or the ferroelectric layer 280.

In the present embodiments, the directional etching process and the wet etching process are selective to the second dielectric layer 234 and does not remove, or substantially, remove portions of the ferroelectric layer 280 or the first metal layer 260. In other words, the directional etching process or the wet etching process is configured to stop on the first metal layer 260.

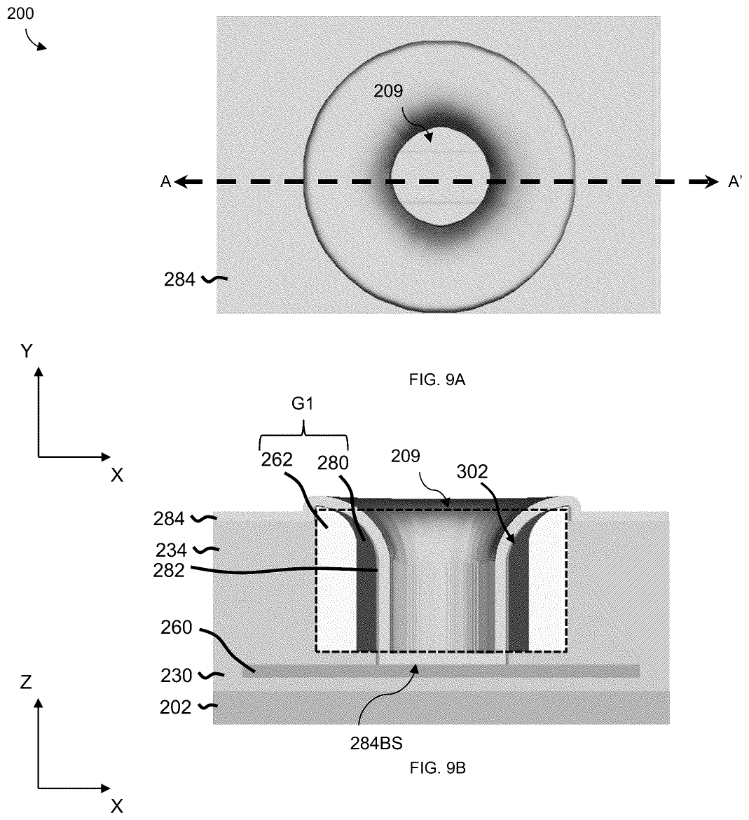

Referring to FIGS. 1, 9A, and 9B, a semiconductor layer 284 is deposited over the semiconductor device 200 at operation 114. In particular, an inner sidewall 302 of the first gate structure G1, which is an inner sidewall of the ferroelectric layer 280, surrounds or wraps around the portion of the semiconductor layer 284 within the opening 209.

In the present embodiments, the semiconductor layer 284 includes a conductive oxide material, such as indium gallium zinc oxide (IGZO), indium tin oxide (ITO), indium zinc oxide (IZO), indium tungsten oxide (IWO), zinc oxide (ZnO), indium oxide (In₂O₃), tin oxide (SnO₂), the like, or combinations thereof. In the present embodiments, the semiconductor layer 284 is conformally deposited in the opening 209 and over the top surface of the second dielectric layer 234 using any suitable process, such as ALD, CVD, PVD, the like, or combinations thereof. In this regard, sidewall portions of the semiconductor layer 284 are formed over the second metal layer 262 and a bottom portion 284BS of the semiconductor layer 284 is formed across and directly (or physically) contacts the exposed portion of the first metal layer 260 in the opening 209.

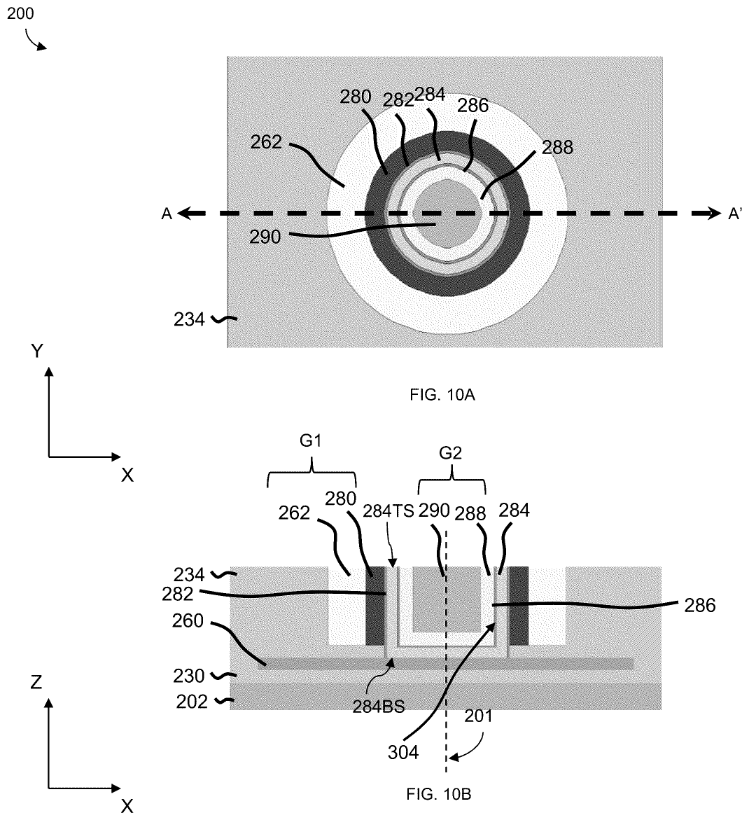

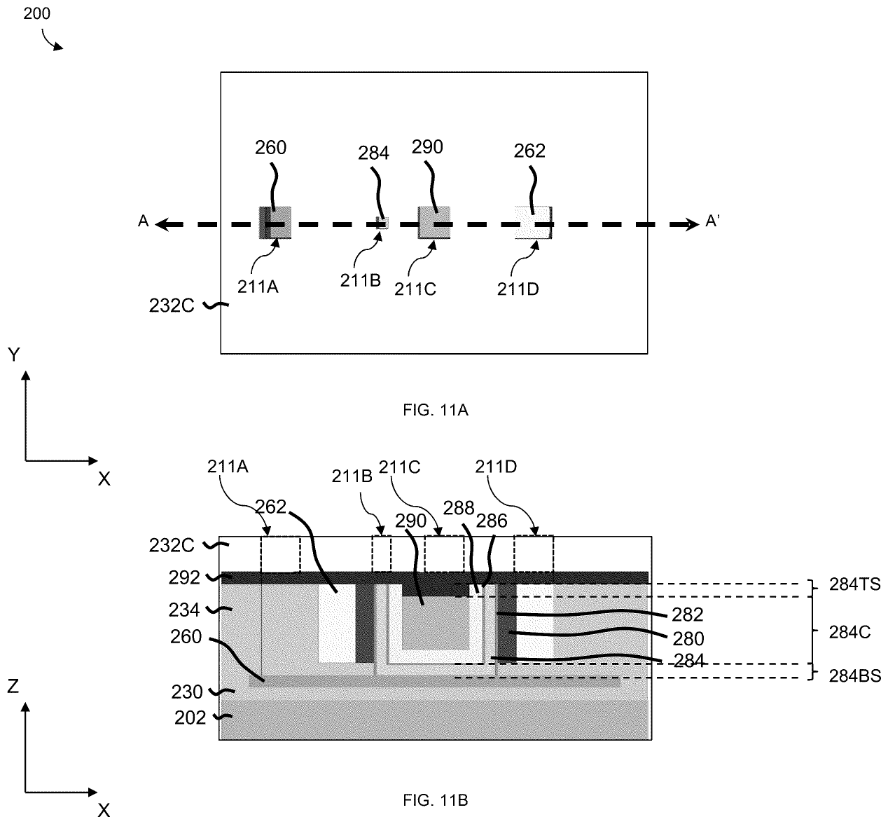

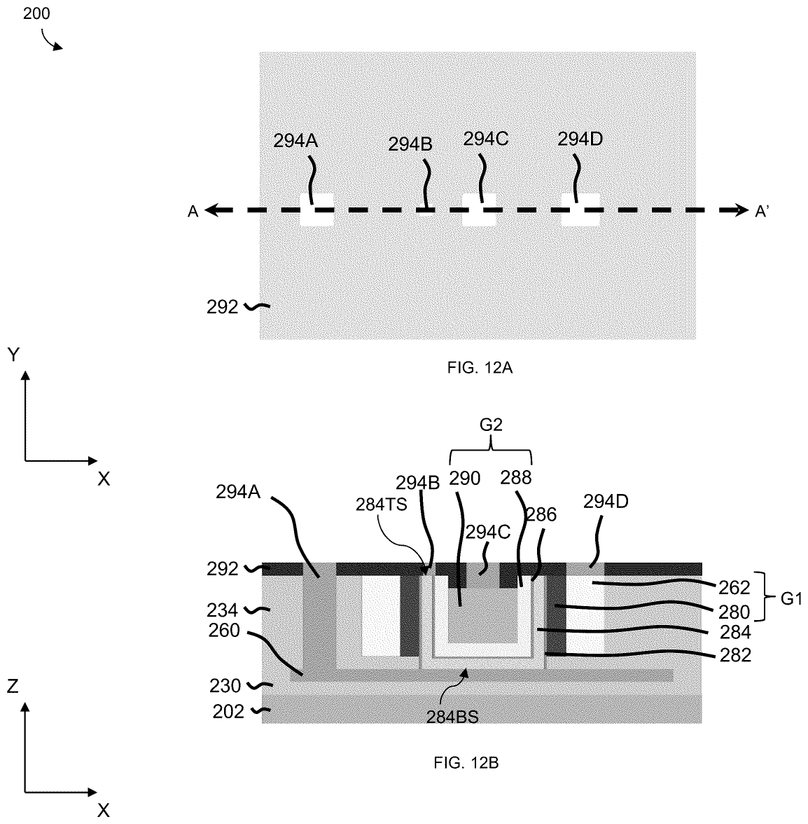

At least a portion of the semiconductor layer 284 is configured as a channel (e.g., channel 284C as depicted in FIG. 11B) engaged with the first gate structure G1 (and a second gate structure G2 formed hereafter). In the present embodiment, the channel extends vertically between the first metal layer 260 (i.e., the first source/drain contact or the bottom contact feature) and a subsequently formed top metal layer (i.e., a second source/drain contact or a top contact feature). Stated differently, the bottom portion 284BS of the semiconductor layer 284 serves as a first source/drain of the semiconductor device 200, and a top portion 284TS (see FIG. 10B) of the semiconductor layer 284 serves as a second source/drain of the semiconductor device 200, where the channel extends vertically therebetween. In this regard, the channel is bounded by, or sandwiched between, the first gate structure G1, which may be referred to as an outer gate structure, and a subsequently formed gate structure (e.g., the second gate structure G2), which may be referred to as an inner gate structure, along a vertical direction (e.g., Z axis). Thus, a conductivity of the channel can be modulated by either or both of the gate structures to correspond to various bit values (when employed as a memory device) or other signals according to a particular application of the semiconductor device 200.

In some embodiments, a first intermediate layer (or first intermediate dielectric layer, first interfacial layer) 282 is formed over the ferroelectric layer 280 before forming the semiconductor layer 284. The first intermediate layer 282 includes any suitable dielectric material, such as silicon oxide. In some embodiments, the first intermediate layer 282 may serve as a gate dielectric layer for the first gate structure G1. The first intermediate layer 282 may be conformally deposited using any suitable process, such as ALD, CVD, PECVD, PVD, the like, or combinations thereof. Subsequently, similar to the directional etching of the second metal layer 262, portions of the first intermediate layer 282 are removed using a directional etching process, such that only sidewall portions of the first intermediate layer 282 remain along the ferroelectric layer 280 in the opening 209. The removal of a bottom portion of the first intermediate layer 282 allows the subsequently formed semiconductor layer 284 to directly contact the first metal layer 260.

Referring to FIGS. 1, 10A, and 10B, a gate dielectric layer 288 and a third metal layer 290 are sequentially deposited over the semiconductor layer 284 at operation 116, such that the semiconductor layer 284 surrounds or wraps around an outer sidewall 304 of the gate dielectric layer 288. The third metal layer 290 is configured as a gate electrode of the second gate structure G2, which further includes the gate dielectric layer 288. Thus, the third metal layer 290 may be alternatively referred to as the second gate electrode 290, and the semiconductor layer 284 is configured to surround or wrap around an outer sidewall of the second gate structure G2.

The gate dielectric layer 288 includes a high-k dielectric material, such as a metal oxide or a silicate of hafnium, aluminum, zirconium, lanthanum, magnesium, barium, titanium, lead, the like, or combinations thereof. The gate dielectric layer 388 may be conformally deposited over the semiconductor layer 284 using any suitable process, such as ALD, CVD, PECVD, PVD, the like, or combinations thereof.

In some embodiments, a second intermediate layer (or second intermediate dielectric layer, or second interfacial layer) 286 is formed over the semiconductor layer 284 before forming the gate dielectric layer 288. The second intermediate layer 286 includes any suitable dielectric material, such as silicon oxide. In some embodiments, the second intermediate layer 286 has the same composition as the first intermediate layer 282 and is conformally deposited by a process similar to that described above with respect to the first intermediate layer 282.

Different from the first intermediate layer 282, however, the directional etching process is omitted after deposition, such that the second intermediate layer 286 remains over a bottom surface and sidewalls of the semiconductor layer 284. In some embodiments, the second intermediate layer 286 is configured to improve adhesion between the semiconductor layer 284 and a subsequently formed gate dielectric layer (e.g., a gate dielectric layer 288).

The third metal layer (or metal fill layer) 290 includes any suitable conductive material (e.g., a metal), such as tungsten, copper, aluminum, ruthenium, cobalt, silver, gold, the like, or combinations thereof. The third metal layer 290 may be deposited using any suitable process, such as CVD, PVD, ALD, electroplating, electroless plating, the like, or combinations thereof, to completely fill the opening 209. Subsequently, at least one CMP process is implemented to remove portions of the one or more of the first intermediate layer 282, the semiconductor layer 284, the second intermediate layer 286, the gate dielectric layer 288, and the third metal layer 290 from the top surface of the second dielectric layer 234.

Thereafter, as depicted in FIG. 11B, the third metal layer 290 is selectively etched with respect to the surrounding components of the semiconductor device 200, to define regions of the semiconductor layer 284 that correspond to the first source/drain (i.e., the bottom portion 284BS), the second source/drain (i.e., the top portion 284TS), and the channel 284C extending therebetween.

In the present embodiments, the gate dielectric layer 288 and the third metal layer 290 together from a second metal gate structure G2, which is referred to as a HKMG. In this regard, the first gate structure (or the outer gate structure) G1, the semiconductor layer 284, and the second gate structure (or the inner gate structure) G2 are arranged concentrically about a central axis 201, where the semiconductor layer 284 extends between the two gate structures. As depicted in FIGS. 3A-10B, the first gate structure G1 encloses or surrounds the semiconductor layer 284, which encloses or surrounds the second gate structure G2.

Referring to FIGS. 1 and 11A-12B, a first contact feature 294A, a second contact feature 294B, a third contact feature 294C, and a fourth contact feature 294D, collectively referred to as contact features 294A-294D, are formed in electrical connection to components of the first gate structure G1, the semiconductor layer 284, and the second gate structure G2 at operation 118.

Referring to FIGS. 11A and 11B, a hard mask layer 292 is formed over the semiconductor device 200 and subsequently patterned to form openings 211A, 211B, 211C, and 211D corresponding to positions of the contact features 294A-294D, respectively. The hard mask layer 292 includes a nitride, an oxide, the like, or combinations thereof. In some embodiments, the hard mask layer 292 is deposited as a blanket layer by a suitable process, such as ALD, CVD, PVD, the like, or combinations thereof.

Subsequently, the hard mask layer 292 is patterned using a series of photolithography and etching processes similar to those described above with respect to patterning the first dielectric layer 230. For example, as depicted, a patterned photoresist layer 232C is formed over the semiconductor device 200 to expose portions of the hard mask layer 292 corresponding to positions of the openings 211A-211D. Though not depicted, the patterned photoresist layer 232C is then used as an etch mask to etch the hard mask layer 292 using a suitable etching process described above, resulting in patterned hard mask layer 292. Portions of the second dielectric layer 234 exposed in the opening 211A are subsequently removed using a different etching process, which stops on the first metal layer 260. After etching the hard mask layer 292, the patterned photoresist layer 232C is removed from the semiconductor device 200 by a suitable process, such as resist stripping or plasma ashing.

Thereafter, referring to FIGS. 12A and 12B, a fourth metal layer 294 is deposited over the semiconductor device 200, thereby filling the openings 211A-211D to form the contact features 294A-294D, respectively. The fourth metal layer 294 includes any suitable conductive material (e.g., a metal), such as tungsten, copper, aluminum, ruthenium, cobalt, silver, gold, the like, or combinations thereof. In some embodiments, the fourth metal layer 294 has the same composition as the first metal layer 260. The fourth metal layer 294 may be deposited using any suitable process, such as CVD, PVD, ALD, electroplating, electroless plating, the like, or combinations thereof. In some embodiments, portions of the fourth metal layer 294 formed over a top surface of the hard mask layer 292 are subsequently removed by a CMP process, thereby planarizing the contact features 294A-294D with the hard mask layer 292.

In the present embodiments, the first contact feature 294A electrically connects (or couples) to the first metal layer 260, which extends along and electrically connects to the bottom portion 284BS of the semiconductor layer 284 configured as the first source/drain of the semiconductor device 200. The second contact feature 294B electrically connects to the top portion 284TS of the semiconductor layer 284 and is thus configured as the second source/drain of the semiconductor device 200. Accordingly, the first metal layer 260 and the contact feature 294A collectively serve as a first source/drain contact and the second contact feature 294B serves as a second source/drain contact of the semiconductor device 200. The third contact feature 294C electrically connects to the third metal layer (or the second gate electrode) 290 of the second gate structure (or the inner gate) G2, and the fourth contact feature 294D electrically connects to the second metal layer (or the first gate electrode) 262 of the first gate structure (or the outer gate) G1.

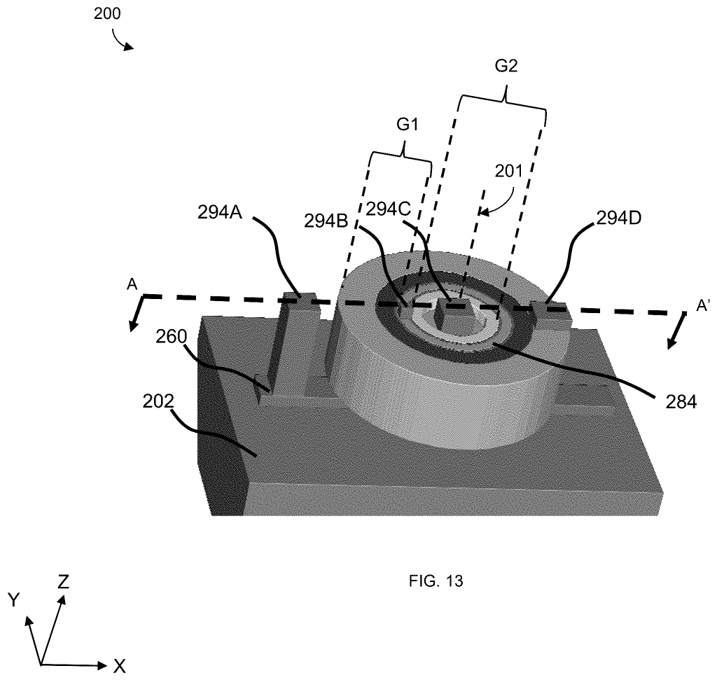

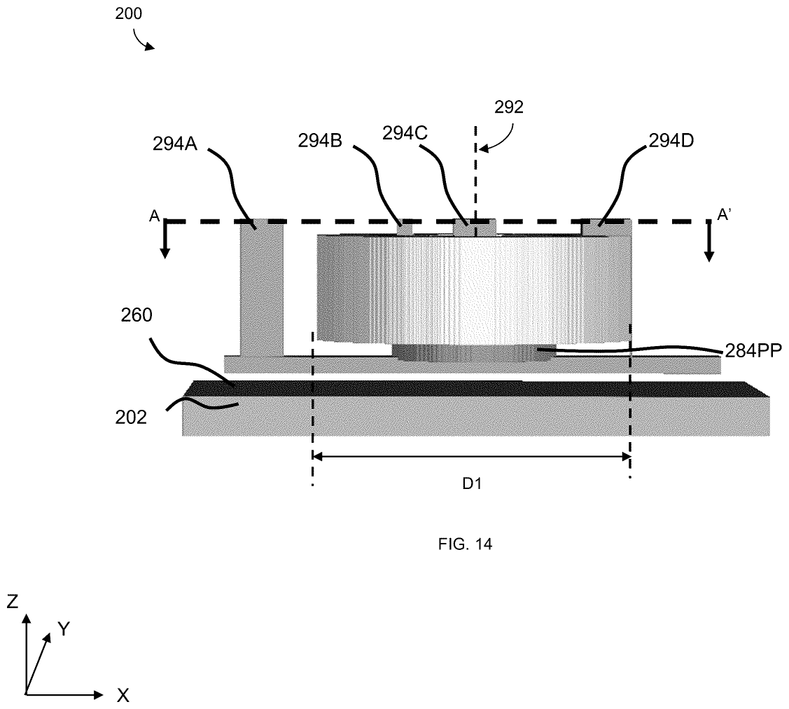

FIGS. 13 and 14 illustrate a 3D perspective view and a 3D side view, respectively, of the semiconductor device 200 corresponding to the embodiment depicted in FIGS. 12A and 12B, with the first dielectric layer 230, the second dielectric layer 234, and the hard mask layer 292 removed merely for clarity purposes. As depicted, the first gate structure G1, the semiconductor layer 284, and the second gate structure G2 are arranged concentrically about the central axis 201, with the second gate structure G2 surrounded by the semiconductor layer 284, which is further surrounded by the first gate structure G1. The first metal layer 260 extends laterally (e.g., along X axis) across a bottom surface of the concentrically arranged structure and directly contacts a protruding portion 284PP of the semiconductor layer 284. In this regard, the first metal layer 260 spans a distance that is greater than a lateral dimension, such as the diameter D1, of the first gate structure G1. In addition, the first metal layer 260 is separated (electrically and physically) from the semiconductor substrate 202.

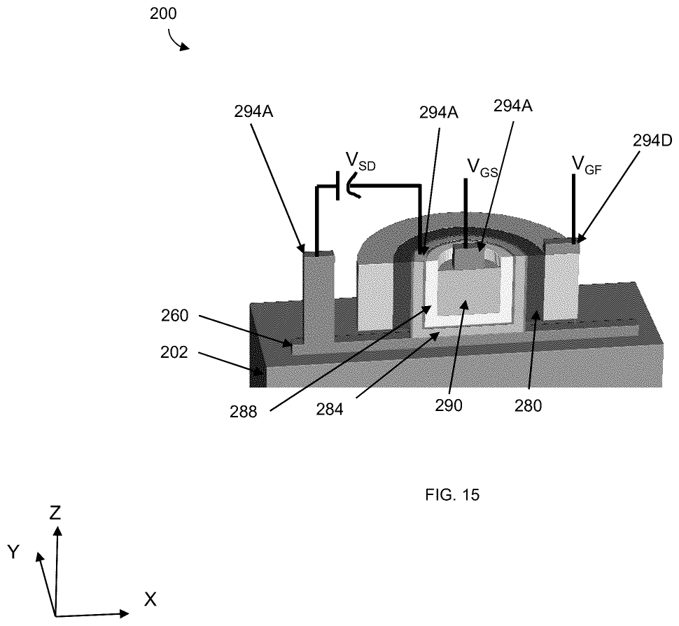

FIG. 15 illustrates a cross-sectional view of the semiconductor device 200 along line AA′ of FIGS. 13 and 14. FIG. 15 additionally illustrates voltages applied at various contact features 294A-294D. In some embodiments, the first gate structure G1 and the second gate structure G2 are employed in a linked manner, to contribute to a same gate voltage, or can be separately controlled. For example, separate control of the first gate structure G1 and the second gate structure G2 may be employed for multi-bit operations.

An example of multi-bit operation is provided in Table 1 below, where a polarization state of the ferroelectric material in the ferroelectric layer 280 is provided as V_{GF}, and a state of the second gate structure G2, the HKMG, is provided as V_{GS}. Of course, this example is not limiting and, according to various embodiments, various currents may be realized, and various bit values can be assigned. Moreover, in some embodiments, V_{GF} and V_{GS} may employ non-binary values to realize additional bits.

TABLE 1
Example Multi-Bit Operation

| V_{GF} | V_{GS} | Bit | Channel | |
|---|---|---|---|---|
| 0 | 0 | 00 | 0 | Power OFF; |
| 1 | 0 | 01 | Medium | Permanent |
| | | | Current | |
| 0 | 1 | 10 | Lower current | Power ON; |
| 1 | 1 | 11 | High Current | Temporary |

Referring to Table 1, each memory block element, such as the semiconductor device 200 provided herein, can produce four different bits corresponding to four different levels of current in the channel of the memory block element. When the ferroelectric material in the ferroelectric layer 280 is programmed, where the bit is switched from “01” to “11,” current in the channel can turn from a medium level to a high level based on the power provided at a switch terminal. When power is off at the switch terminal, where the bit is switched from “11” to “00,” the memory block element can hold the charge permanently due to the ferroelectric property of the first gate structure G1. In addition, to read and write, power is needed at the switch terminal in a temporary state.

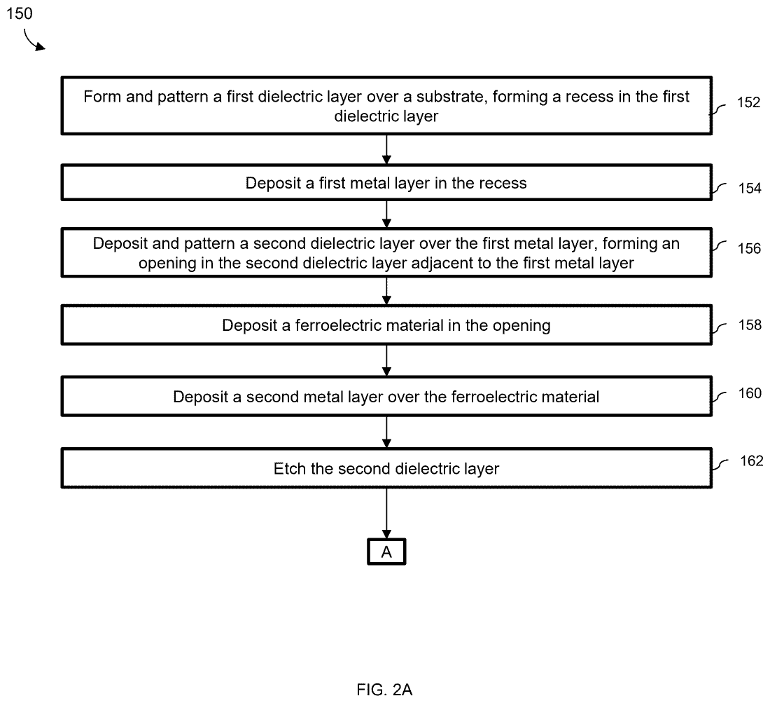

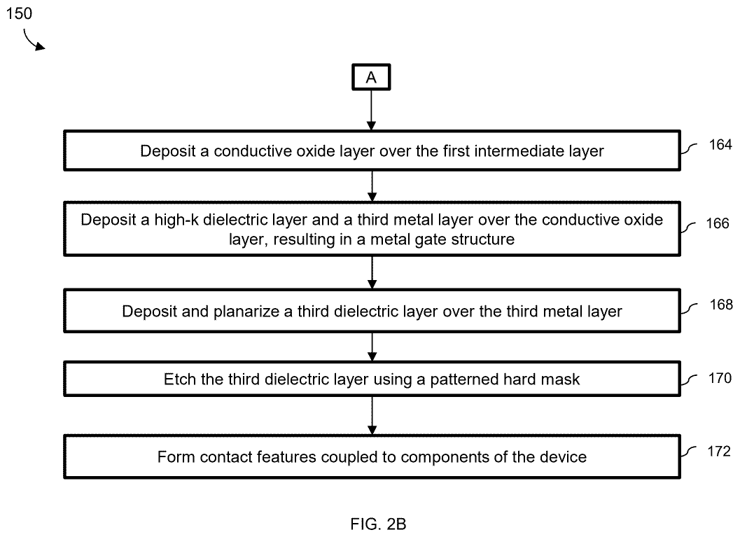

FIGS. 2A and 2B collectively illustrate a flowchart of an example method 150 for forming an embodiment of a semiconductor device 300. The semiconductor device 300 can include a memory block element, such as memory block elements for a non-volatile memory device, similar to the semiconductor device 200 described above. Various memory block elements can be interconnected to form arrays. For example, various instances of the memory cells formed according to the method 1500 may be laterally spaced from each other (e.g., according to a row or column). Further, various instances of the memory block elements formed according to the method 150 may be stacked over each other, such as in a repeating pattern. The various interconnections can be connected to form logical rows, columns, pages, blocks, and so forth.

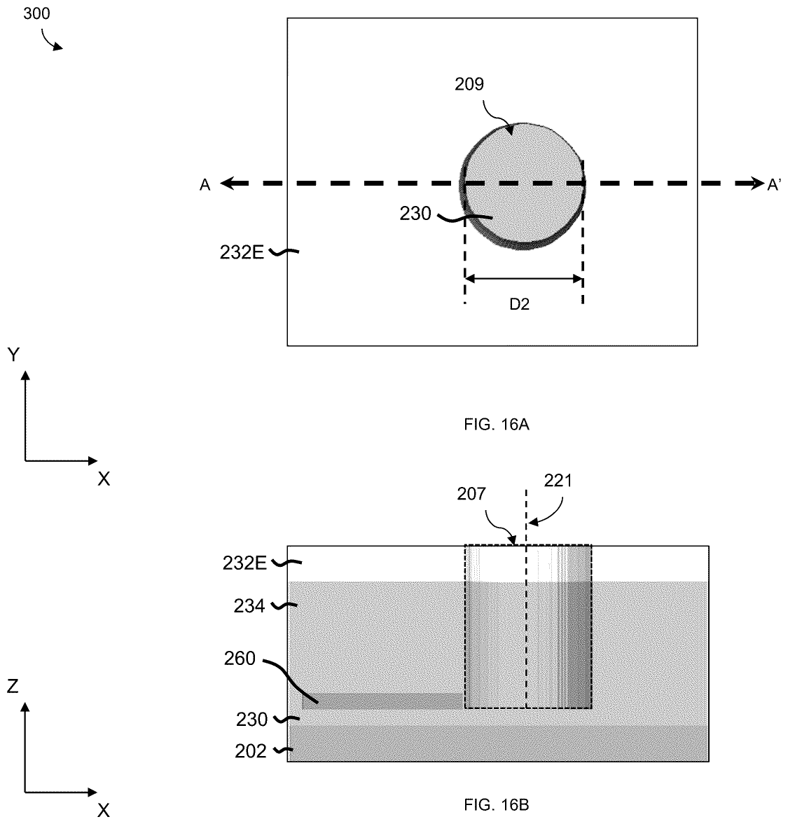

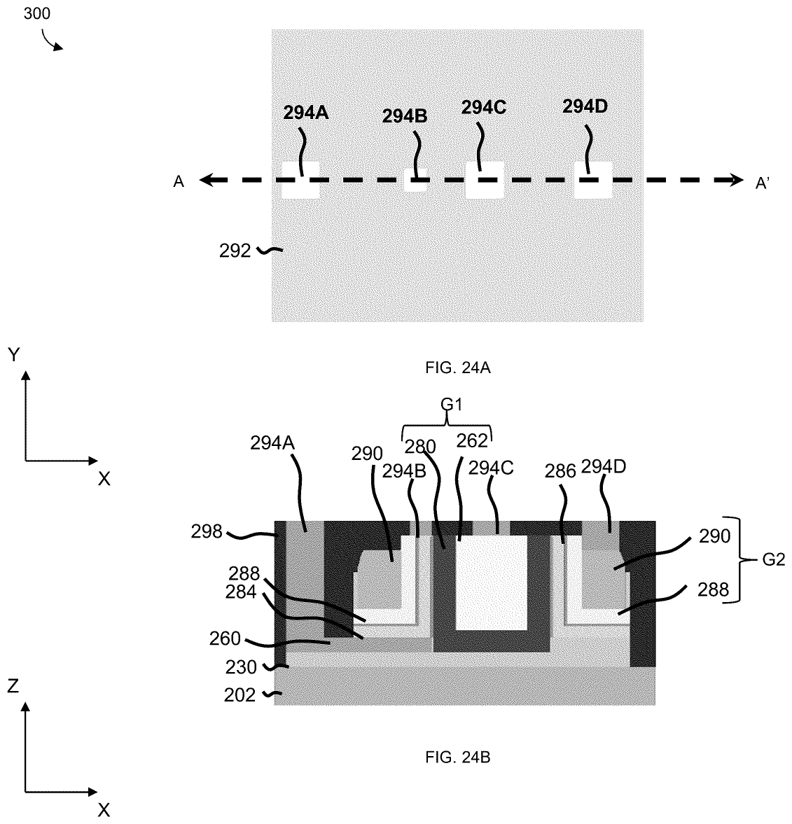

In various embodiments, operations of the method 150 may be associated with top, cross-sectional, or other views of an example semiconductor device at various fabrication stages as shown in FIGS. 16A-26, which will be discussed in further detail below. It should be understood that the semiconductor device 300, shown in FIGS. 16A-26, may include a number of other devices such as inductors, fuses, capacitors, coils, etc., while remaining within the scope of the present disclosure. For example, a semiconductor device can include further layers of stacked transistors or channel portions thereof and interconnections therebetween. For purposes of clarity, components of the semiconductor device 300 similar to those of the semiconductor device 200 are described using the same reference numerals, and operations of the method 150 similar to those of the method 100 are not described in detail.

Referring to FIGS. 2A, 16A, and 16B, portions of the semiconductor device 300 similar to those of the semiconductor device 200 are formed at operations 152, 154, and 156. For example, while not depicted herein, the first dielectric layer 230 is formed over the semiconductor substrate 202 and subsequently patterned to form a recess (not depicted) at operation 152, which is similar to the operation 102. The first metal layer 260 is then deposited to fill the recess and planarized to expose a top surface of the first dielectric layer 230 at operation 154, which is similar to the operation 104.

Subsequently, referring to FIGS. 16A and 16B, the second dielectric layer 234 is deposited over the first metal layer 260 and patterned using a patterned photoresist layer 232E to form an opening 207 in the second dielectric layer 234 at operation 156, which is similar to the operation 106. However, different from the semiconductor device 200, the opening 207 of the semiconductor device 300 is formed at a position laterally adjacent to (or offset from), rather than directly below, the first metal layer 260. Additionally, the opening 207 is configured with a diameter D2 that is less than the diameter D1 of the opening 209 in the semiconductor device 200. In this regard, the patterned photoresist layer 232E is configured differently from the patterned photoresist layer 232A with respect to a position and a size of the opening that corresponds to the opening 207. After etching the second dielectric layer 234 to form the opening 207, the patterned photoresist layer 232E is removed from the semiconductor device 200 by a suitable process, such as resist stripping or plasma ashing.

The opening 207 is centered about a central axis 221 extending along Z axis, similar to the central axis 201 through a center of the opening 209. In some embodiments, the first metal layer 206 is physically separated from the opening 207, such that a separation distance between a sidewall of the first metal layer 206 and a sidewall of the opening 207 is greater than zero. In some embodiments, the sidewall of the first metal layer 206 directly (or physically) contacts the sidewall of the opening 207, such that the separation distance is about zero.

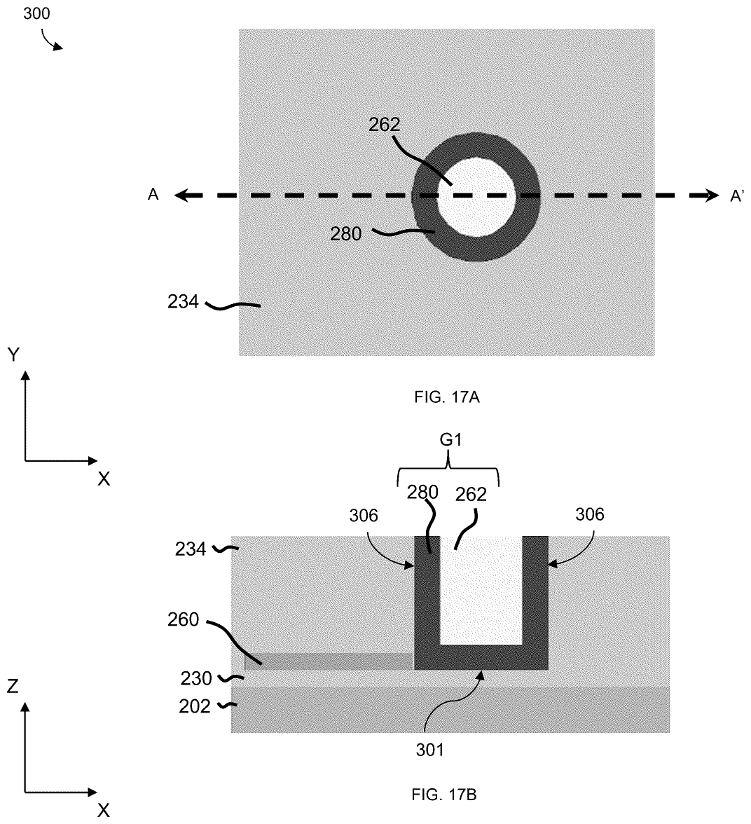

Referring to FIGS. 2A, 17A, and 17B, the ferroelectric layer 280 is conformally deposited in the opening 207 at operation 158, which is similar to the operation 110 depicted in FIGS. 7A and 7B with the exception that no directional etching is needed to remove the bottom portion of the ferroelectric layer 280 in the opening 207. In this regard, the ferroelectric layer 280 is formed along a bottom surface and sidewalls of the opening 207.

Still referring to FIGS. 2A, 17A, and 17B, the second metal layer 262 is deposited over the ferroelectric layer 280 to fill the opening 209 at operation 160, which is similar to the operation 108 depicted in FIGS. 6A and 6B with the exception that no directional etching is needed to remove the bottom portion of the second metal layer 262 in the opening 207. The resulting second metal layer 262 is embedded in the ferroelectric layer 280. Subsequently, at least one CMP process is performed to remove portions of the ferroelectric layer 280 and the second metal layer 262 from the top surface of the second dielectric layer 234, resulting in the first gate structure G1 that completely fills the opening 207. As depicted, the first metal layer 260 is laterally adjacent to an outer sidewall 306 of the first gate structure G1, which is also an outer sidewall of the ferroelectric layer 280. In some embodiments, the first metal layer 260 directly (or physically) contacts the outer sidewall 306. In some embodiments, the first metal layer 260 is physically separated from the outer sidewall 306. In addition, the bottom portion 301 of the first gate structure G1 is adjacent to the first metal layer 260 and electrically and physically separated from the semiconductor substrate 202.

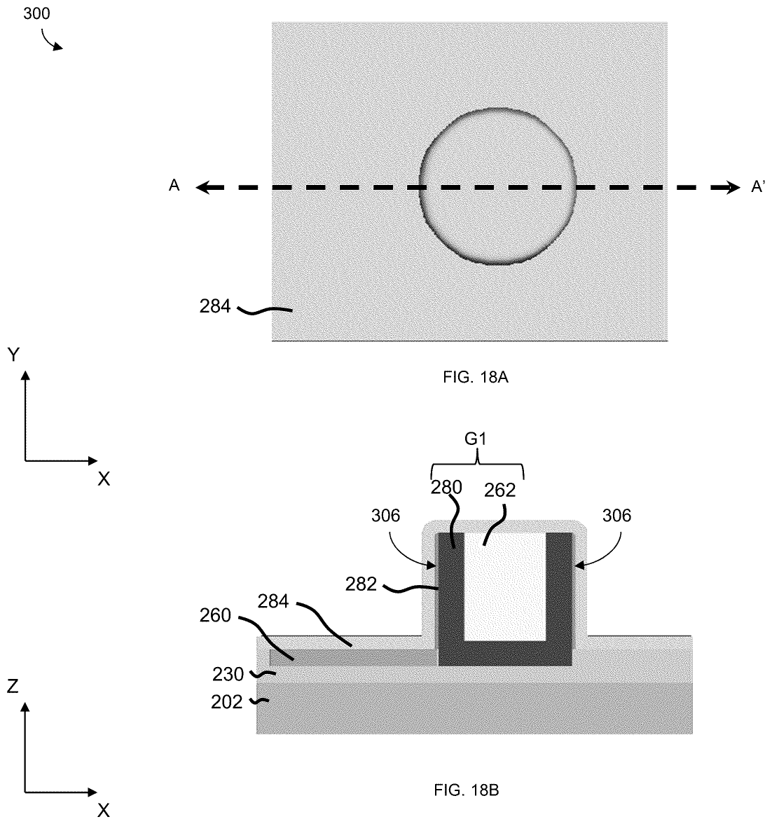

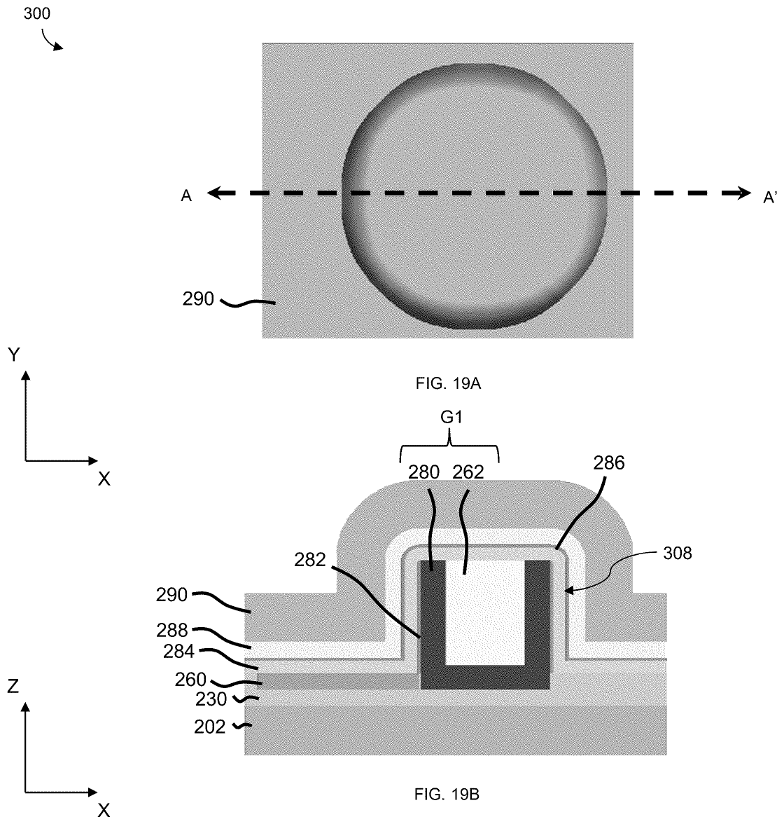

Referring to FIGS. 2A, 18A, and 18B, a portion of the second dielectric layer 234 adjacent to the opening 207 is etched to expose the underlying first metal layer 260 at operation 162, which is similar to the operation 112 depicted in FIGS. 8A and 8B.

Still referring to FIGS. 2B, 18A, and 18B, the semiconductor layer 284 is conformally deposited over the semiconductor device 300 at operation 164, which is similar to the operation 114 depicted in FIGS. 9A and 9B. With respect to the semiconductor device 300, the semiconductor layer 284 is conformally formed over exterior surfaces, thereby surrounding at least portions of the outer sidewall 306 of the first gate structure G1. In contrast, the semiconductor layer 284 in the semiconductor device 200 is formed within an interior of the first gate structure G1 and therefore does not surround the outer sidewall 306 of the first gate structure G1. Furthermore, as described above, the first intermediate layer 282 is conformally deposited over the semiconductor device 300 and directionally etched before forming the semiconductor layer 284, such that portions of the first intermediate layer 282 are disposed between the sidewalls of the ferroelectric layer 280 and the sidewalls of the semiconductor layer 284.

Referring to FIGS. 2B, 19A, and 19B, the gate dielectric layer 288 and the third metal layer 290 are conformally deposited over the semiconductor layer 284 at operation 166, which is similar to the operation 116 depicted in FIGS. 10A and 10B. In particular, portions of the gate dielectric layer 288 surround an outer sidewall 308 of the semiconductor layer 284. Furthermore, as described above, the second intermediate layer 286 is conformally deposited over the semiconductor layer 284 before forming the gate dielectric layer 288.

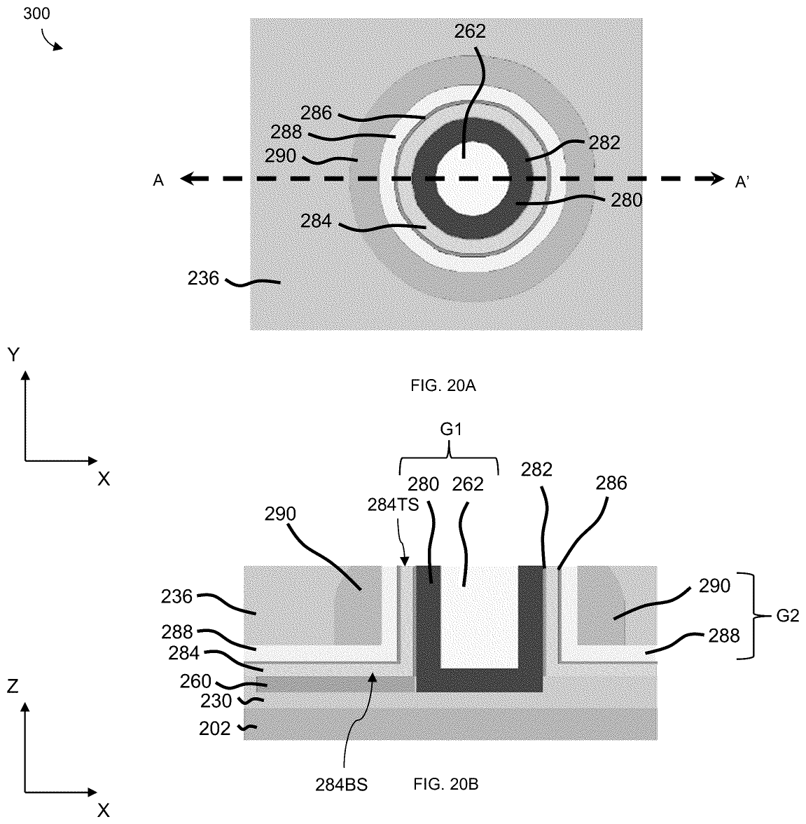

Referring to FIGS. 2B, 20A, and 20B, a third dielectric layer 236 is deposited as a blanket layer over the semiconductor device 300 and subsequently planarized by at operation 168, resulting in the second gate structure G2 that includes the third metal layer 290 over the gate dielectric layer 288.

The third dielectric layer 236 includes an oxide, a nitride, a low-k dielectric material, the like, or combinations thereof. For example, the third dielectric layer 236 may include silicon oxide, PSG, BSG, BPSG, USG, the like, or combinations thereof. In some embodiments, the third dielectric layer 236 has the same composition as the first dielectric layer 230 and is formed by a process similar to that described above with respect to forming the first dielectric layer 230. The third dielectric layer 236 is planarized using at least one CMP process to expose the first gate structure G1, i.e., the top surfaces of the ferroelectric layer 280 and the second metal layer 262. The resulting second gate structure G2 encloses or surrounds a sidewall of the semiconductor layer 284, which encloses or surrounds a sidewall of the first gate structure G1.

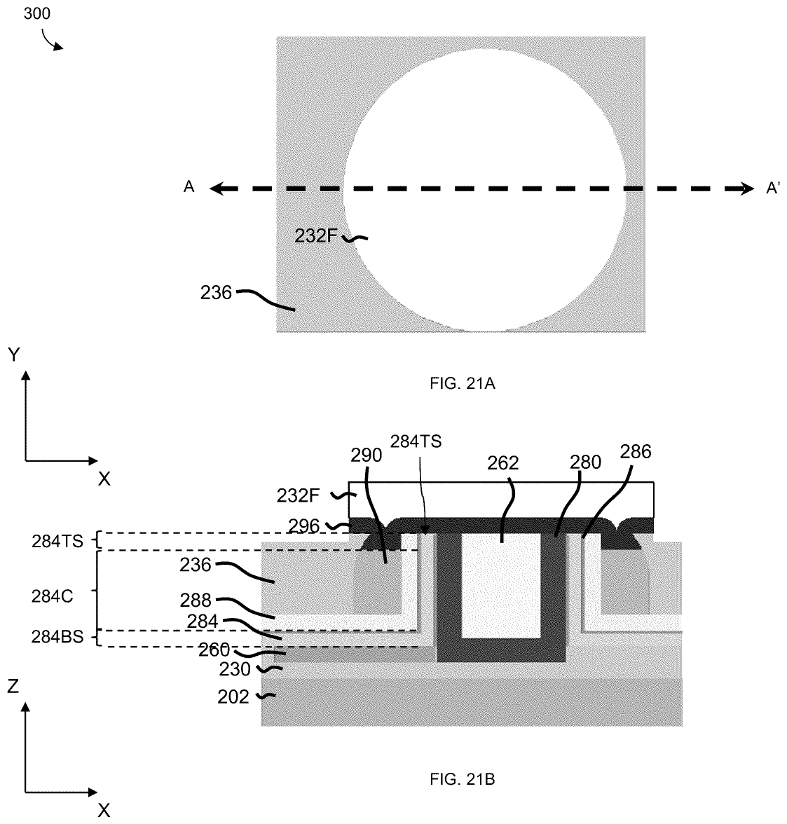

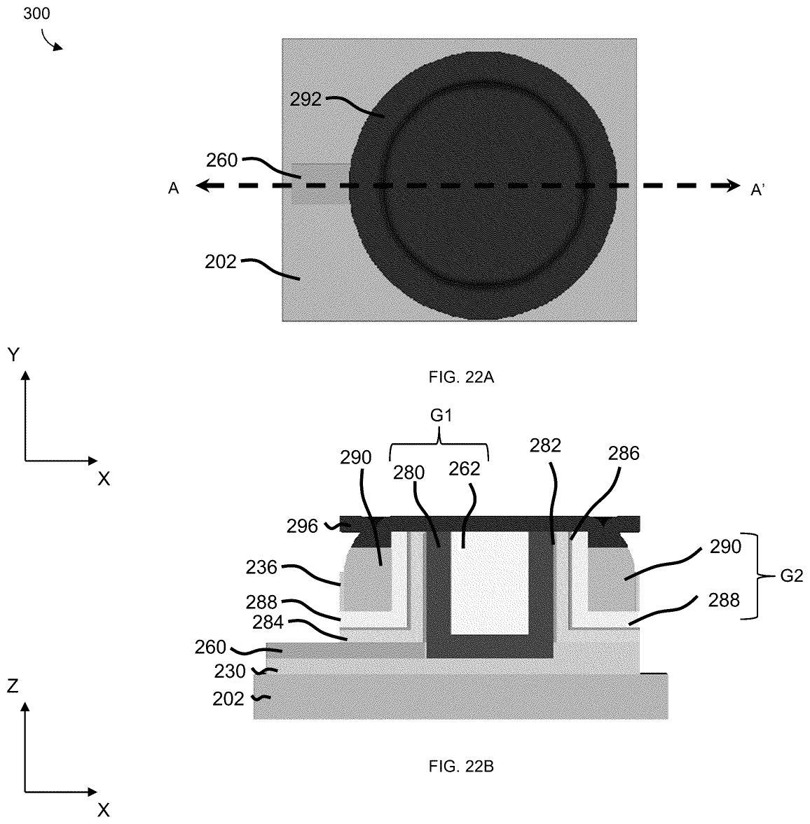

Similar to the coupling between the first metal layer 260 and the semiconductor layer 284 in the semiconductor device 200, the first metal layer 260 is coupled to the bottom portion 284BS of the semiconductor layer 284, which acts as the first source/drain of the semiconductor device 300 and is opposite to the second source/drain of the semiconductor device 300 provided at the top portion 284TS of the semiconductor layer 284. In this regard, the channel (e.g., the channel 284C as depicted in FIG. 21B) of the semiconductor device 300, as a portion of the semiconductor layer 284, extends vertically between the top portion 284TS and the bottom portion 284BS, and the first metal layer (or the bottom contact feature) 260 acts as the first source/drain contact of the semiconductor device 300.

Referring to FIGS. 2B and 21A-22B, portions of the third dielectric layer 236, the gate dielectric layer 288, the semiconductor layer 284, the first intermediate layer 282, and the second intermediate layer 286 are removed using a patterned hard mask layer 296 at operation 170, thereby exposing the first metal layer 260.

In some embodiments, referring to FIGS. 21A and 21B, the third metal layer 290 is selectively etched with respect to the surrounding components of the semiconductor device 200, forming a recess (not depicted) to define regions of the semiconductor layer 284 that correspond to the first source/drain (i.e., the bottom portion 284BS), the second source/drain (i.e., the top portion 284TS), and the channel 284C extending therebetween. Subsequently, a hard mask layer 296 is deposited as a blanket layer over the semiconductor device 300 and patterned using a patterned photoresist layer 232F to protect portions of the hard mask layer 296 overlaying the first gate structure G1 and the second gate structure G2.

The hard mask layer 296 includes a nitride, an oxide, the like, or combinations thereof. In some embodiments, the hard mask layer 296 and the hard mask layer 292 have the same composition. In some embodiments, the hard mask layer 296 is deposited as a blanket layer by a suitable process, such as ALD, CVD, PVD, the like, or combinations thereof. The hard mask layer 296 may be patterned by a series of photolithography and etching processes similar to those described above with respect to patterning the first dielectric layer 230. For example, as depicted, the patterned photoresist layer 232F is formed over the hard mask layer 296 to expose portions of the hard mask layer 296 not overlaying the first gate structure G1 and the second gate structure G2. The patterned photoresist layer 232F is then used as an etch mask to etch the hard mask layer 296 using a suitable etching process described above, resulting in the patterned hard mask layer 296 as depicted in FIG. 21B. After performing the etching process, the patterned photoresist layer 232F is removed from the semiconductor device 300 by a suitable process, such as resist stripping or plasma ashing.

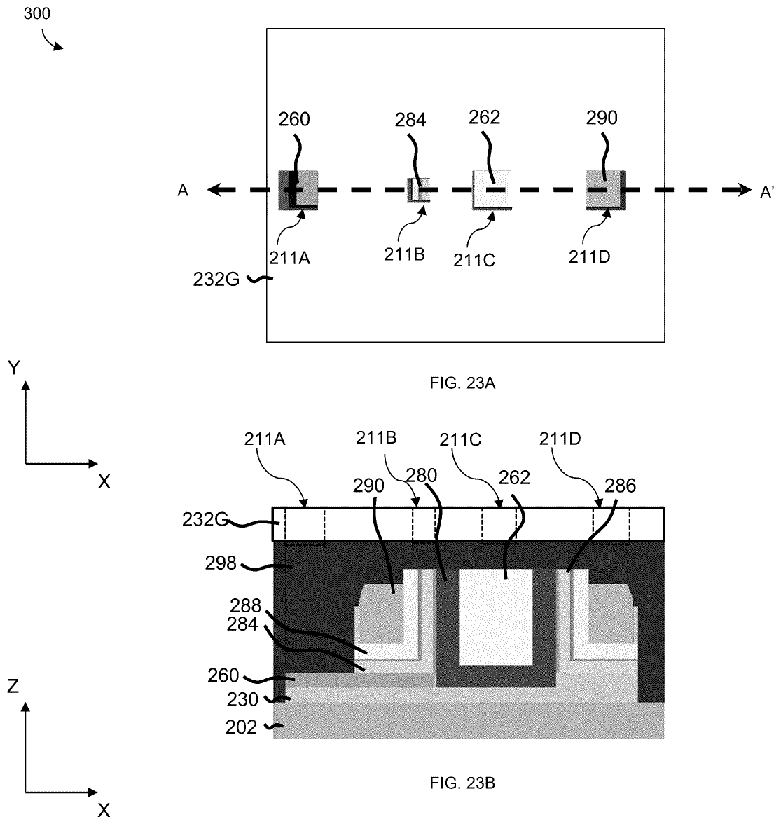

Thereafter, referring to FIGS. 22A and 22B, portions of the third dielectric layer 236, the gate dielectric layer 288, the semiconductor layer 284, the first intermediate layers 282, and the second intermediate layer 286 exposed by the patterned hard mask layer 296 are removed by one or more suitable etching processes described above. Accordingly, fabrication of the second gate structure G2 is completed. In some embodiments, portions of the third dielectric layer 236 remain over a sidewall of the third metal layer 290.

Referring to FIGS. 2B and 23A-24B, the first contact feature 294A, the second contact feature 294B, the third contact feature 294C, and the fourth contact feature 294D, collectively referred to as contact features 294A-294D, are formed in electrical connection to components of the first gate structure G1, the semiconductor layer 284, and the second gate structure G2 at operation 172, which is similar to the operation 118 depicted in FIGS. 11A-12B.

Different from the semiconductor device 200, referring to FIGS. 11A and 11B, a fourth dielectric layer 298 is deposited over the semiconductor device 300 as a blanket layer, where the fourth dielectric layer 298 may have a composition different from the underlying first dielectric layer 230 and may have the same composition as the hard mask layer 296. After depositing the fourth dielectric layer 298 by a suitable process, such as CVD, PVD, ALD, HDP-CVD, FCVD, spin coating, the like, or combinations thereof, the fourth dielectric layer 298 is patterned to form the openings in a manner similar to patterning the hard mask layer 292 as depicted in FIGS. 11A and 11B using a patterned photoresist layer 232G, for example. Subsequently, referring to FIGS. 24A and 24B, the fourth metal layer 294 is deposited and planarized over the semiconductor device 300 as a blanket layer to form the contact features 294A-294D as described above with respect to forming the semiconductor device 200. For example, in the depicted embodiments, the first contact feature 294A electrically connects to the first metal layer (or the bottom contact) 260 and the second contact feature 294B electrically connects to the top portion 284TS of the semiconductor layer 284. Accordingly, the first metal layer 260 and the contact feature 294A collectively serve as the first source/drain contact and the second contact feature 294B serves as the second source/drain contact of the semiconductor device 300.

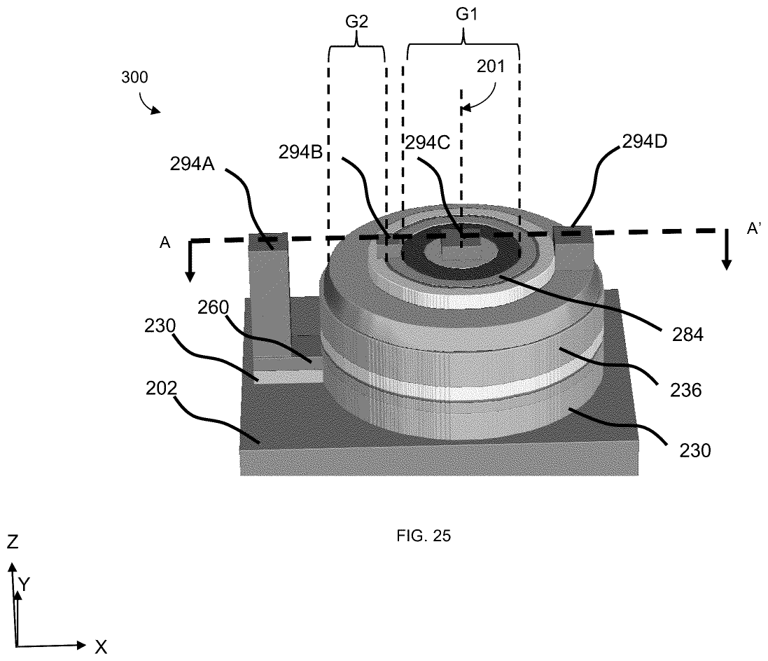

FIG. 25 illustrates a 3D perspective view of the semiconductor device 300 corresponding to the embodiment depicted in FIGS. 24A and 24B, with the first dielectric layer 230, the second dielectric layer 234, and the hard mask layer 292 removed merely for clarity purposes. As depicted, the first gate structure G1, the semiconductor layer 284, and the second gate structure G2 are arranged concentrically about the central axis 201, with the first gate structure G1 surrounded by the semiconductor layer 284, which is further surrounded by the second gate structure G2. The first metal layer 260 is adjacent to the bottom surface of the concentrically arranged structure and directly contacts the bottom portion 284BS of the semiconductor layer 284.

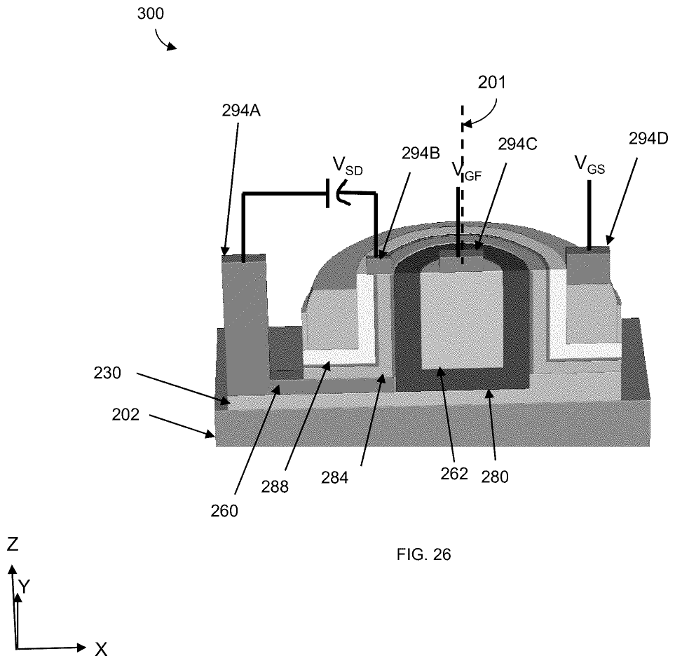

FIG. 26 illustrates a cross-sectional view of the semiconductor device 300 along line AA′ of FIG. 25. FIG. 26 additionally illustrates voltages applied at various contact features 294A-294D. In comparison to the semiconductor device 200 depicted in FIG. 15, due to the difference in the configuration in which the first gate structure G1, the semiconductor layer 284, and the second gate structure G2 are arranged, locations at where the V_{GS} and the V_{GF} are applied also differ. However, the multi-bit operations of the semiconductor device 300 in response to the applied voltage are the same as those of the semiconductor device 200 as described in detail above (see Table 1).

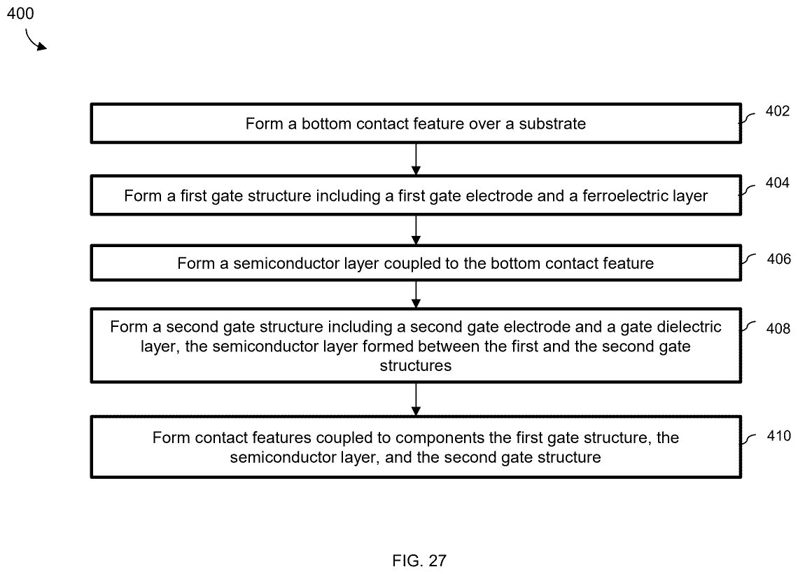

According to some embodiments of the present disclosure, referring to FIG. 27, a method 400 for forming an embodiment of a semiconductor device including a memory block element is provided. The method 400 may overlap with aspects of the method 100 and the method 150 described herein. The method 400 includes an operation 402 during which a bottom contact feature, such as the first metal layer 260, is formed over a substrate, such as the semiconductor substrate 202. The method 400 includes an operation 404 during which a first gate structure, such as the first gate structure G1 including the second metal layer 262 and the ferroelectric layer 280, is formed. The method 400 includes an operation 406 during which a semiconductor layer, such as the semiconductor layer 284, is formed, where the semiconductor layer is coupled to the bottom contact feature. A first intermediate layer, such as the first intermediate layer 282, may be formed between the ferroelectric layer and the semiconductor layer. The method 400 includes an operation 408 during which a second gate structure, such as the second gate structure G2 including the third metal layer 290 and the gate dielectric layer 288, is formed. A second intermediate layer, such as the second intermediate layer 286, may be formed between the gate dielectric layer and the semiconductor layer. The semiconductor layer is formed between the first gate structure G1 and the second gate structure G2. In particular, the semiconductor layer is formed between the ferroelectric layer and the gate dielectric layer. The method 400 further includes an operation 410 during which contact features, such as the contact features 294A-294D, are formed and coupled to components of the first gate structure, the semiconductor layer, and the second gate structure.

As depicted in one or more of FIGS. 3A-26, the configuration in which the bottom contact feature, the first gate structure, the semiconductor layer, and the second gate structure are arranged may vary. For example, in some embodiments, referring to the semiconductor device 200 depicted in FIGS. 3A-15, the semiconductor layer surrounds an outer sidewall of the second gate structure G2, the first gate structure G1 surrounds the semiconductor layer, and the bottom contact feature extends across at least a bottom portion of the first gate structure G1. In some embodiments, referring to the semiconductor device 300 depicted in FIGS. 16A-26, the semiconductor layer surrounds an outer sidewall of the first gate structure G1, the second gate structure G2 surrounds the semiconductor layer, and an entirety of the bottom contact feature is adjacent to, rather than below, a sidewall of the ferroelectric layer.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments. [00103]“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a first gate structure comprising a first gate electrode and a ferroelectric layer;
a second gate structure comprising a second gate electrode and a gate dielectric layer; and
a semiconductor layer disposed between the ferroelectric layer and the gate dielectric layer, wherein the first gate structure, the semiconductor layer, and the second gate structure are arranged concentrically.

2. The semiconductor device of claim 1, wherein the semiconductor layer surrounds an outer sidewall of the first gate structure.

3. The semiconductor device of claim 1, wherein the semiconductor layer surrounds an outer sidewall of the second gate structure.

4. The semiconductor device of claim 1, wherein the semiconductor layer comprises a conductive oxide material.

5. The semiconductor device of claim 1, wherein a bottom portion of the semiconductor layer extends along a bottom portion of the gate dielectric layer.

6. The semiconductor device of claim 1, further comprising:
a first intermediate dielectric layer extending between the ferroelectric layer and the semiconductor layer; and
a second intermediate dielectric layer extending between the semiconductor layer and the gate dielectric layer.

7. The semiconductor device of claim 1, further comprising:
a first source/drain contact electrically coupled to a bottom portion of the semiconductor layer; and
a second source/drain contact electrically coupled to a top portion of the semiconductor layer.

8. The semiconductor device of claim 7, wherein an entirety of the first source/drain contact is adjacent to a sidewall of the ferroelectric layer.

9. The semiconductor device of claim 7, wherein a portion of the first source/drain contact is below the ferroelectric layer.

10. A semiconductor device, comprising:
an inner gate structure comprising an inner gate electrode disposed over a ferroelectric layer;
a semiconductor layer wrapping around the inner gate structure and comprising a conductive oxide; and
an outer gate structure wrapping around the semiconductor layer, the outer gate structure comprising a second gate electrode disposed over a gate dielectric layer, wherein the inner gate structure, the semiconductor layer, and the outer gate structure are arranged concentrically.

11. The semiconductor device of claim 9, wherein the inner gate electrode is embedded in the ferroelectric layer.

12. The semiconductor device of claim 9, further comprising:
a first source/drain contact electrically coupled to a bottom portion of the semiconductor layer, wherein the first source/drain contact is laterally adjacent to a bottom portion of the ferroelectric layer; and
a second source/drain contact electrically coupled to a top portion of the semiconductor layer opposite the bottom portion.

13. The semiconductor device of claim 12, wherein the first source/drain contact extends along the bottom portion of the semiconductor layer.

14. The semiconductor device of claim 12, wherein the first source/drain contact directly contacts a portion of the inner gate structure.

15. The semiconductor device of claim 12, wherein the first source/drain contact is physically separated from a portion of the inner gate structure.

16. A method, comprising:
forming a first gate structure over a substrate, the first gate structure comprising a first gate electrode and a ferroelectric layer;
forming a second gate structure comprising a second gate electrode and a gate dielectric layer; and
forming a semiconductor layer sandwiched between the ferroelectric layer and the gate dielectric layer, wherein the first gate structure, the semiconductor layer, and the second gate structure are formed concentrically.

17. The method of claim 16, wherein:
the step of forming the first gate structure comprises:
forming an opening over the substrate,
depositing the ferroelectric layer in the opening, and
depositing the first gate electrode over the ferroelectric layer to fill the opening, the step of forming the semiconductor layer comprises depositing the semiconductor layer over the ferroelectric layer, and
the step of forming the second gate structure comprises:
depositing the gate dielectric layer over the semiconductor layer; and
forming the second gate electrode over the gate dielectric layer.

18. The method of claim 17, further comprising forming a bottom contact feature adjacent to the opening before depositing the ferroelectric layer, wherein the semiconductor layer is formed to directly contact the bottom contact feature.

19. The method of claim 16, wherein:
the step of forming the first gate structure comprises:
forming an opening over the substrate,
forming the first gate electrode within the opening, and
depositing the ferroelectric layer over the first gate electrode in the opening,
the step of forming the semiconductor layer comprises depositing the semiconductor layer over the ferroelectric layer in the opening, and
the step of forming the second gate structure comprises:
depositing the gate dielectric layer over the semiconductor layer, and
forming the second gate electrode over the gate dielectric layer to fill the opening.

20. The method of claim 19, further comprising:
forming a bottom contact feature over and separated from the substrate before forming the opening; and
etching the first gate electrode and the ferroelectric layer to expose the bottom contact feature in the opening, such that the semiconductor layer is formed to directly contact the bottom contact feature.
